(19) United States
(12) Patent Application Publication
(10) Pub. No.: US 2025/0220881 A1
(43) Pub. Date: Jul. 3, 2025

(54) SEMICONDUCTOR MEMORY CELL STRUCTURE INCLUDING A VERTICAL CHANNEL

(71) Applicant: Taiwan Semiconductor Manufacturing Company, Ltd., Hsinchu (TW)

(72) Inventors: Chen-Jun WU, Hsinchu City (TW); Chih-Yu CHANG, New Taipei City (TW); Chien-Hao HUANG, Hsinchu City (TW); Yen-Chung HO, Hsinchu (TW); Yong-Jie WU, Tainan City (TW); Katherine H. CHIANG, New Taipei City (TW)

(21) Appl. No.: 18/398,882

(22) Filed: Dec. 28, 2023

(51) Int. Cl. H10B 12/00

(52) U.S. Cl. CPC H10B 12/33; H10B 12/05

(57) ABSTRACT

A semiconductor device includes a memory cell structure that includes a transistor structure and a storage structure. A gate electrode of the transistor structure extends in a direction that is approximately perpendicular to a surface of a substrate of the semiconductor device, which enables the gate length to be increased with minimal to no increase in horizontal or lateral size of the memory cell structure. A channel layer may be a U-shaped layer in that the channel layer is included on at least two of the sidewalls and on the bottom surface of the gate electrode. This increases the channel area of the transistor structure, which enables a low current leakage to be achieved for the memory cell structure, and enables a high lateral density of memory cell structures to be achieved in the semiconductor device.

### BACKGROUND

A non-volatile memory cell is a type of memory cell that may include a transistor connected in series with a memory element such as a capacitor, a phase change material layer, a resistive layer, and/or a magnetic layer, among other examples. This may be referred to as a one transistor-one memory element (1T-1X). The memory element in a 1T-1X cell selectively stores data (e.g., a logical “1” value or a logical “0” value) based on an electric charge, a resistivity, a capacitance, and/or a magnetic field, among other examples. The state of the memory element may be selectively modified and/or read by using the transistor to charge or discharge the memory element.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of an example semiconductor device described herein.

FIGS. 3A-3D are diagrams of an example implementation of a memory cell structure described herein.

FIGS. 4A-4X are diagrams of an example implementation of forming a memory cell structure described herein.

FIGS. 5A and 5B are diagrams of an example implementation of a memory cell structure described herein.

FIGS. 6A-6F are diagrams of an example implementation of forming a memory cell structure described herein.

FIGS. 7A and 7B are diagrams of an example implementation of a memory cell structure described herein.

FIGS. 8A-8D are diagrams of an example implementation of forming a memory cell structure described herein.

FIGS. 9A and 9B are diagrams of an example implementation of a memory cell structure described herein.

FIGS. 10A-10D are diagrams of an example implementation of forming a memory cell structure described herein.

FIG. 11 is a diagram of example components of a device described herein.

FIG. 12 is a flowchart of an example process associated with forming a memory cell structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A memory element of a memory cell structure (e.g., a 1T-1X memory cell structure) may be configured to store data in the absence of applied power for long durations of time. Current leakage through a transistor of the memory cell structure can negatively impact the memory element's ability to store data for long durations of time. For example, if the memory element is implemented by a capacitor, current leakage through the transistor can drain an electric charge stored in the capacitor, thereby resulting in data loss. As a result, the memory element may need to be periodically “refreshed” (e.g., the charge stored in the memory element may need to be replenished) in order to prevent data loss. This increases the power consumption of the memory cell structure, which decreases the power efficiency of the memory cell structure. Increasing a gate length of the transistor may decrease the current leakage through the transistor at the expense of reduced memory cell density in a semiconductor device in which the memory cell structure is included.

In some implementations described herein, a semiconductor device includes a memory cell structure (e.g., a 1T-1X memory cell structure) that includes a transistor structure and a storage structure corresponding to the memory element of the memory cell structure. The gate electrode of the transistor structure extends in a vertical direction in the semiconductor device (e.g., a z-direction that is approximately perpendicular to a surface of a substrate of the semiconductor device), which enables the gate length to be increased with minimal to no increase in horizontal or lateral (e.g., x-y direction) size of the memory cell structure. A channel layer may be a U-shaped channel layer in that the channel layer is included on at least two of the sidewalls and on the bottom surface of the gate electrode. This increases the channel area of the transistor structure, which enables a low current leakage to be achieved for the memory cell structure, and enables a high horizontal or lateral density of memory cell structures to be achieved in the semiconductor device. The low current leakage of the memory cell structure enables data stored in the storage structure of the memory cell structure to retain data for longer time durations between refreshes, which reduces the power consumption of the memory cell structure and increases the power efficiency of the memory cell structure.

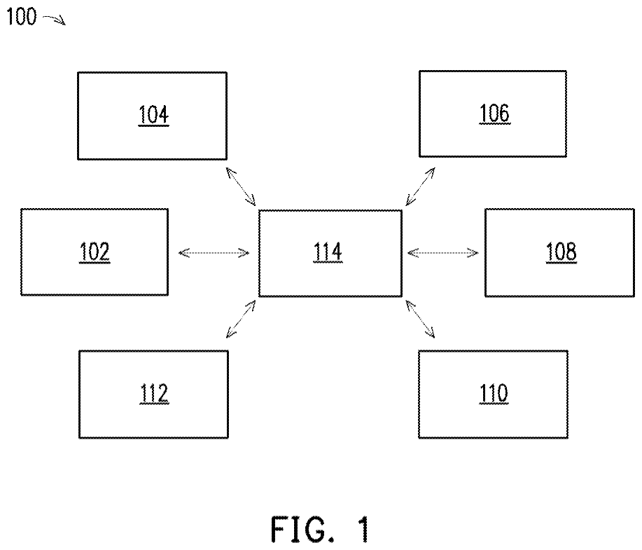

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

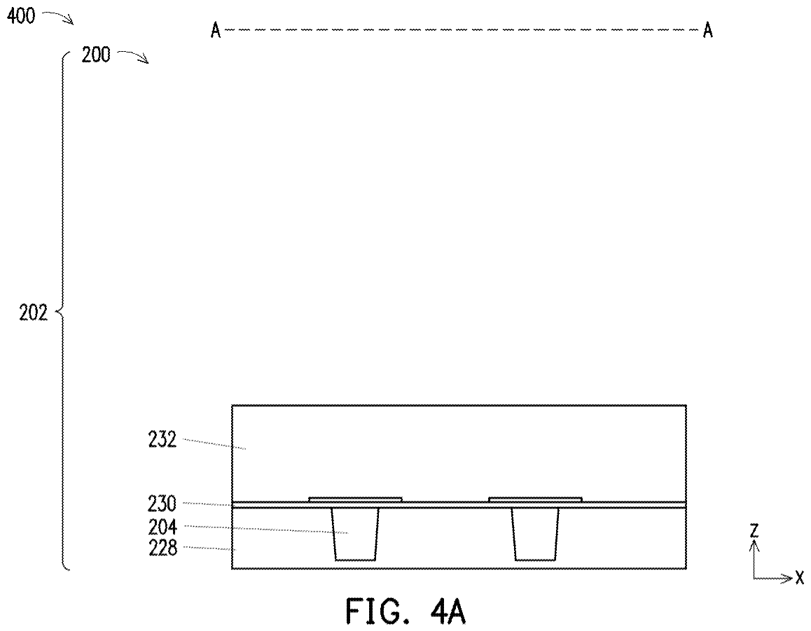

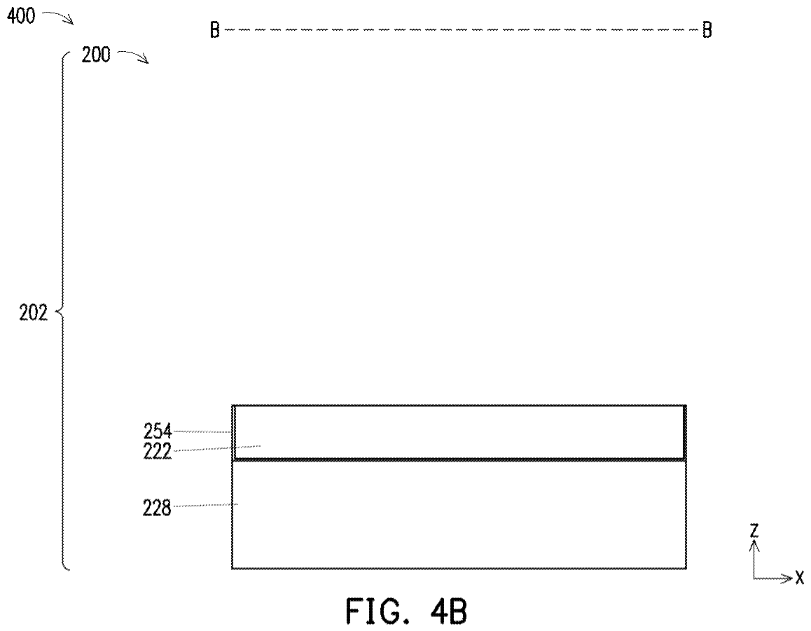

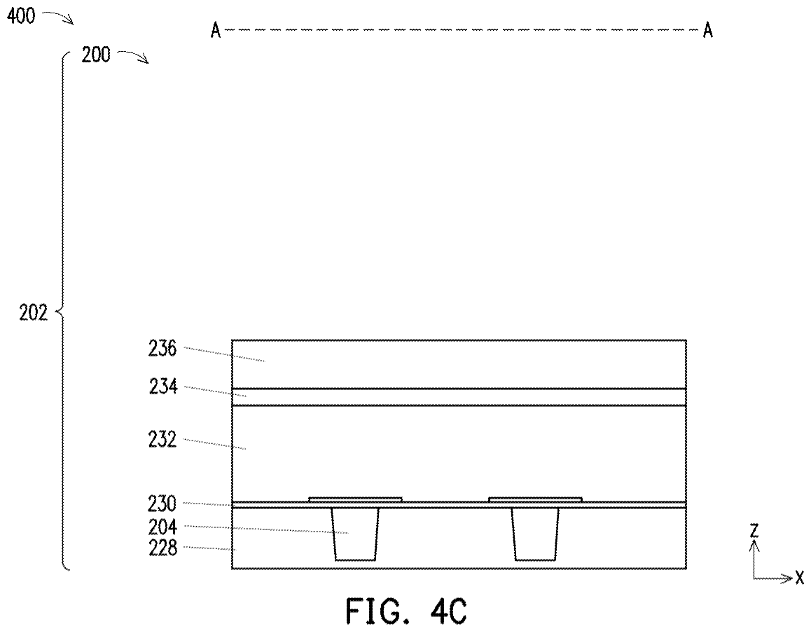

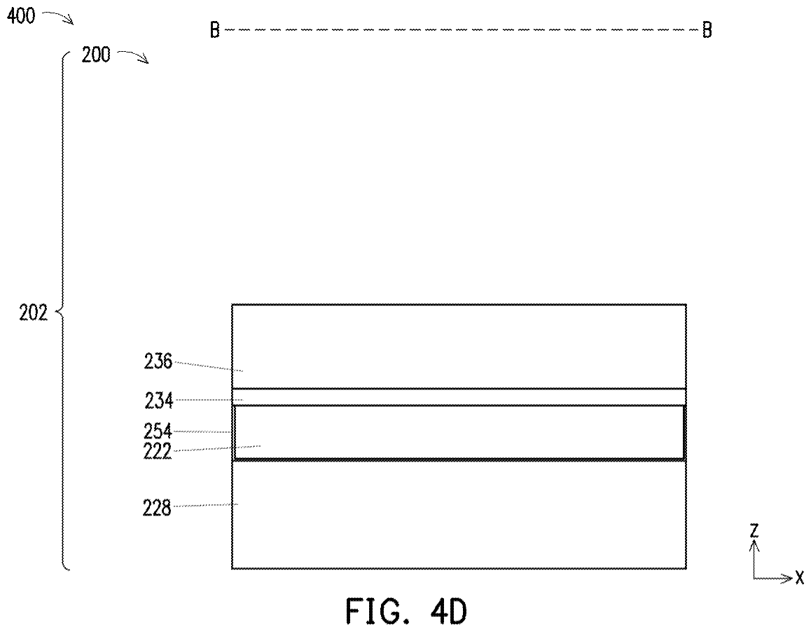

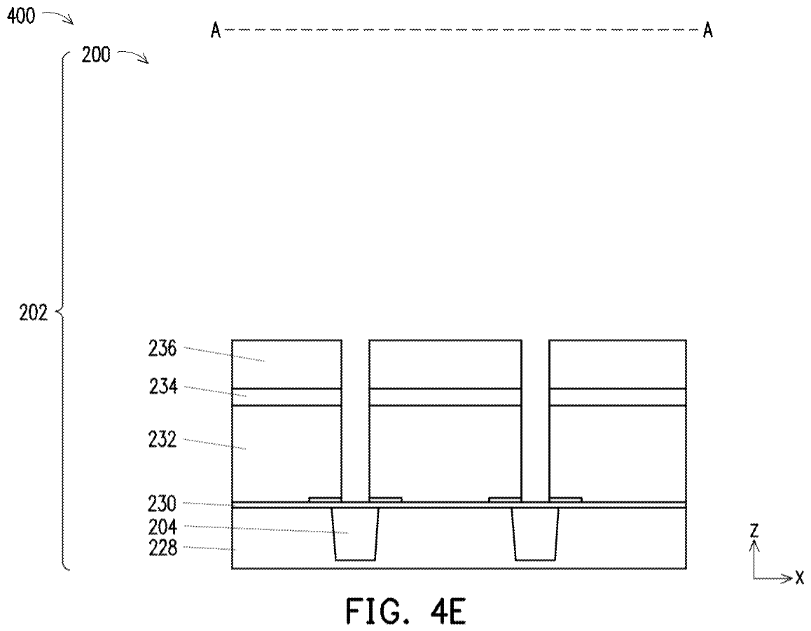

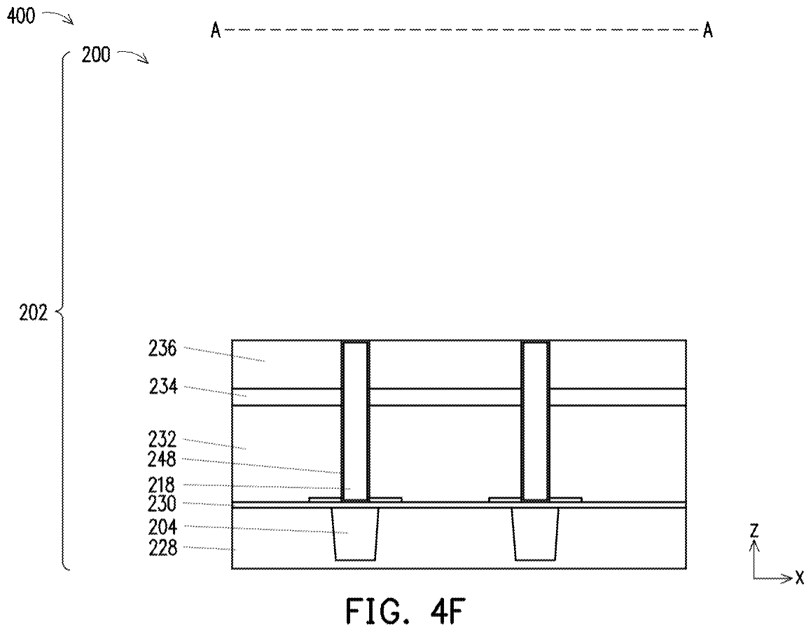

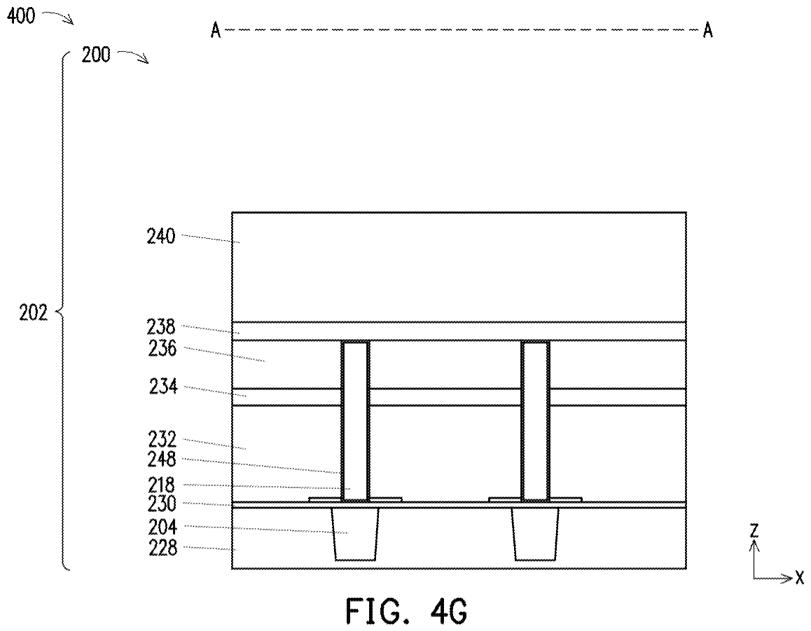

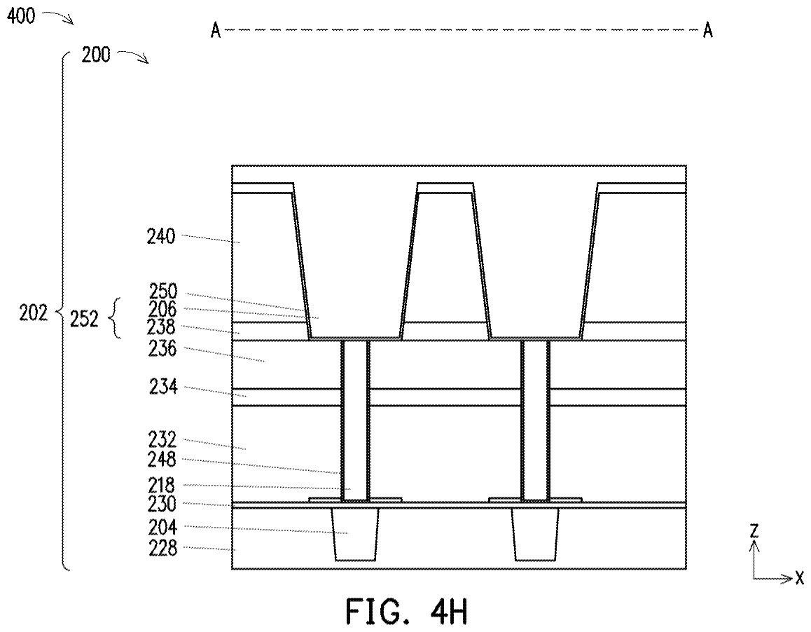

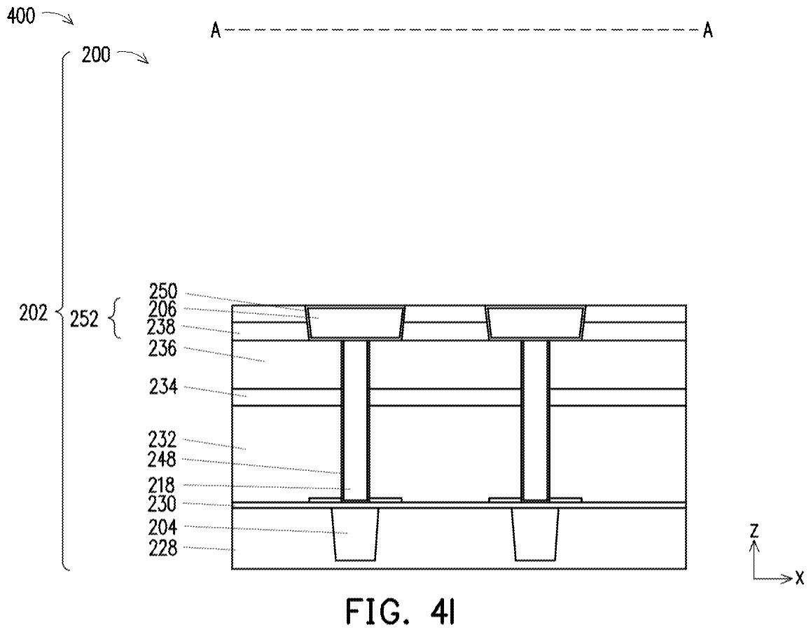

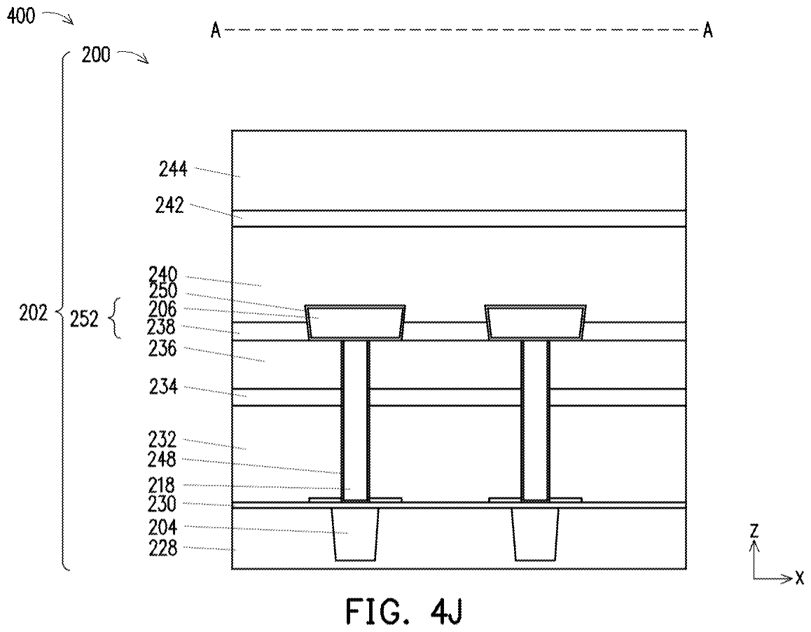

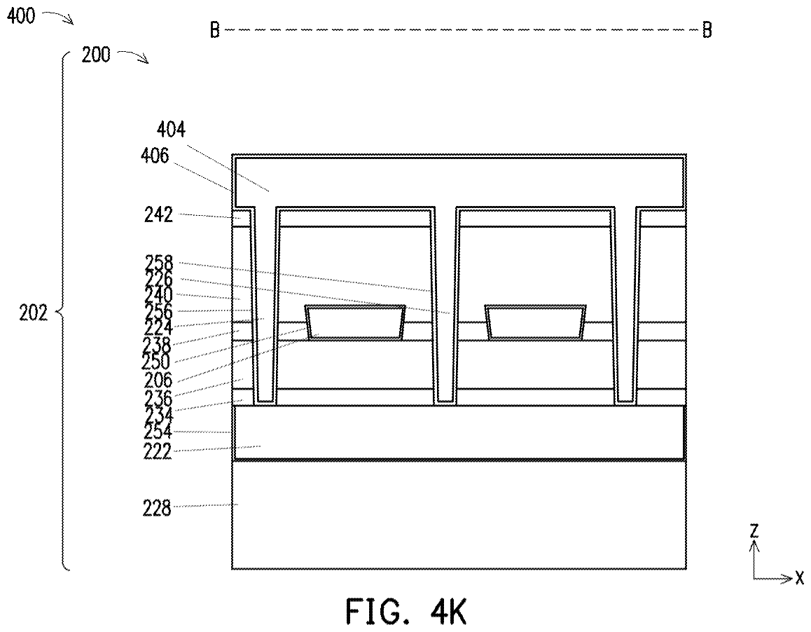

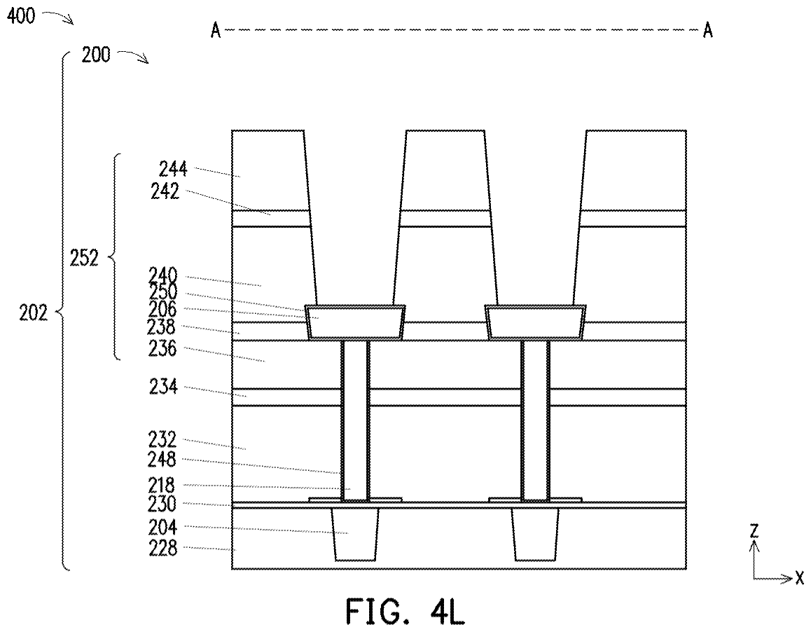

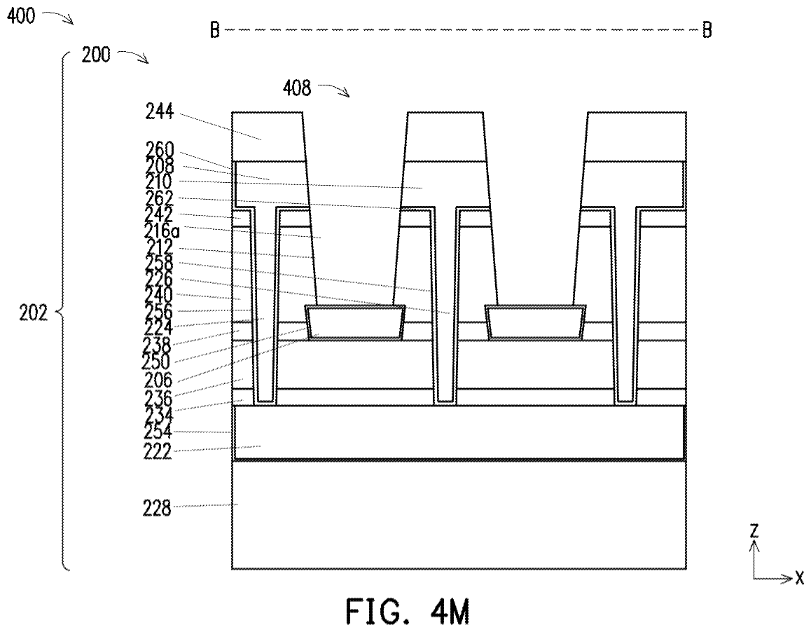

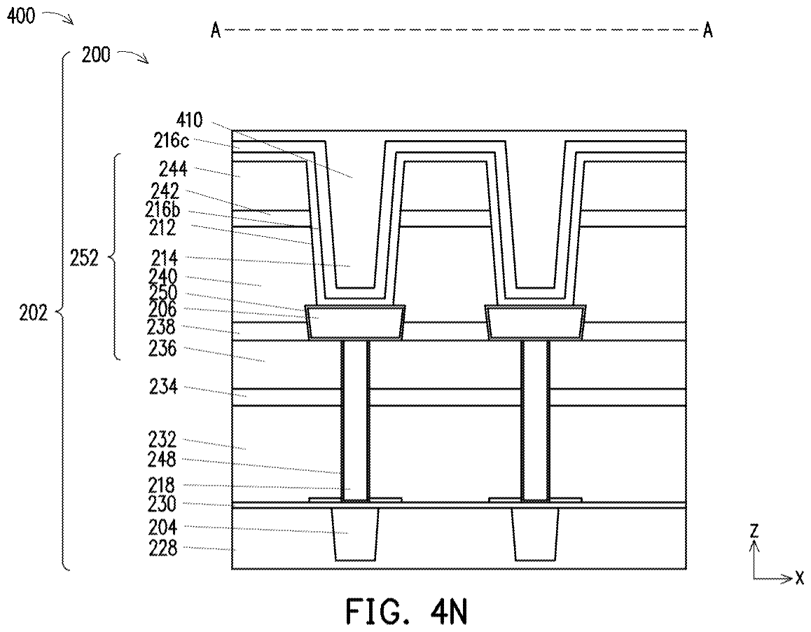

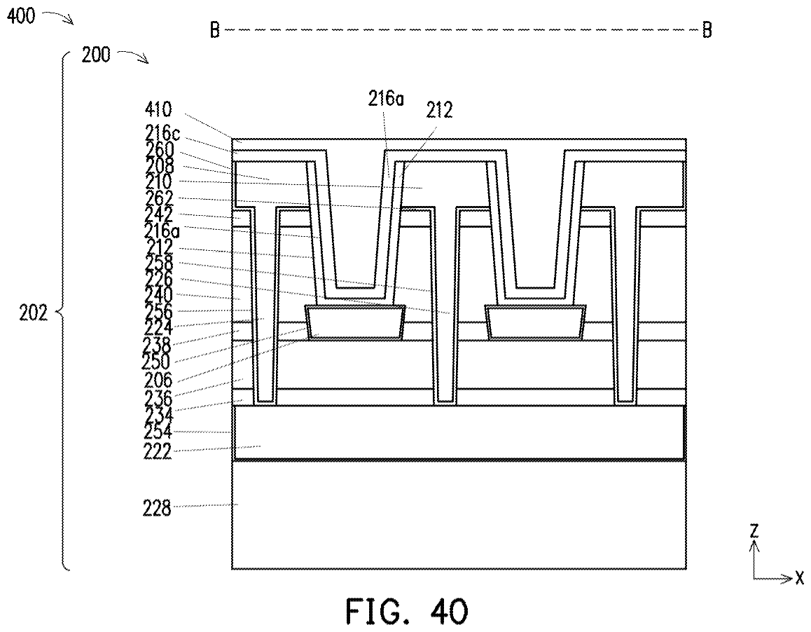

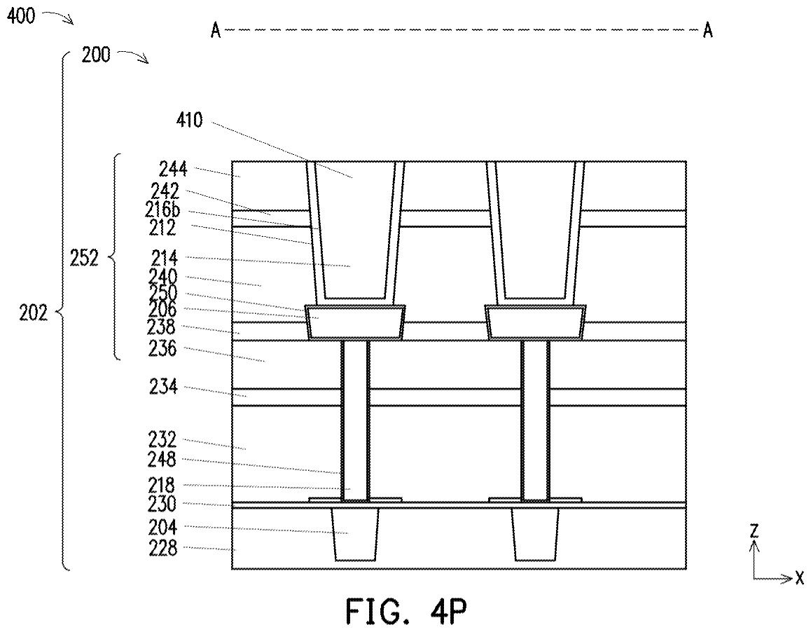

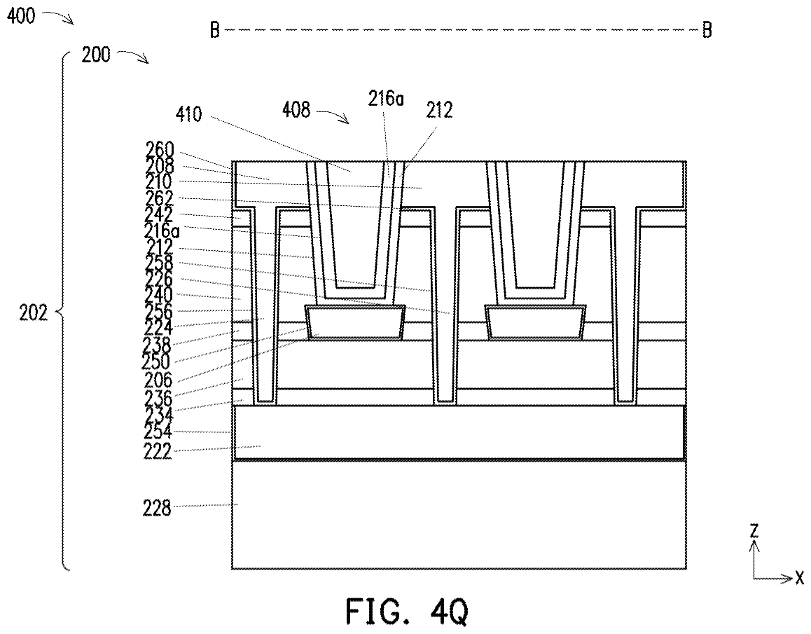

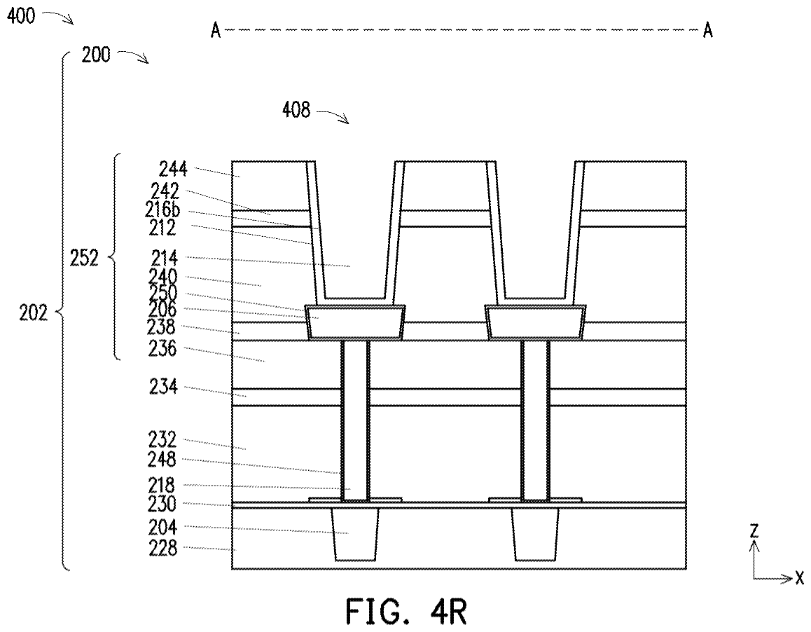

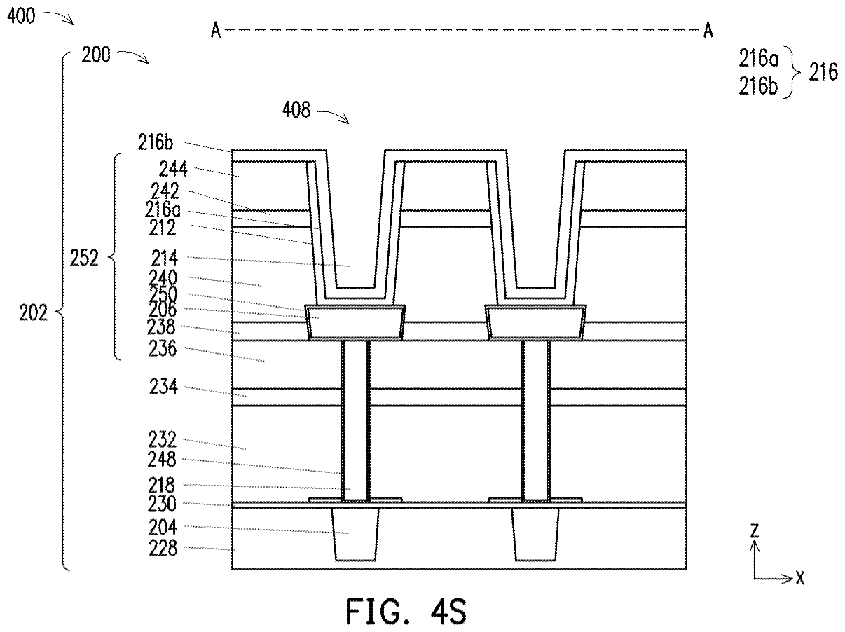

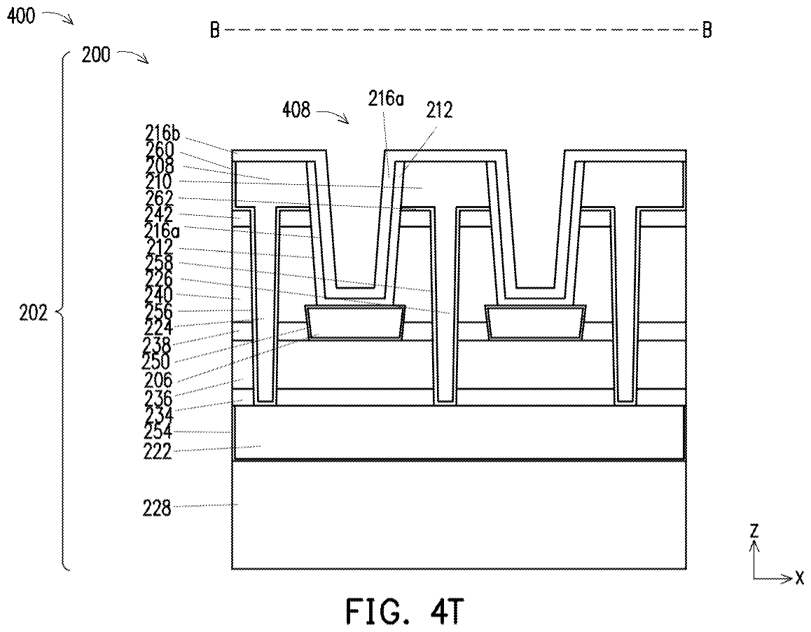

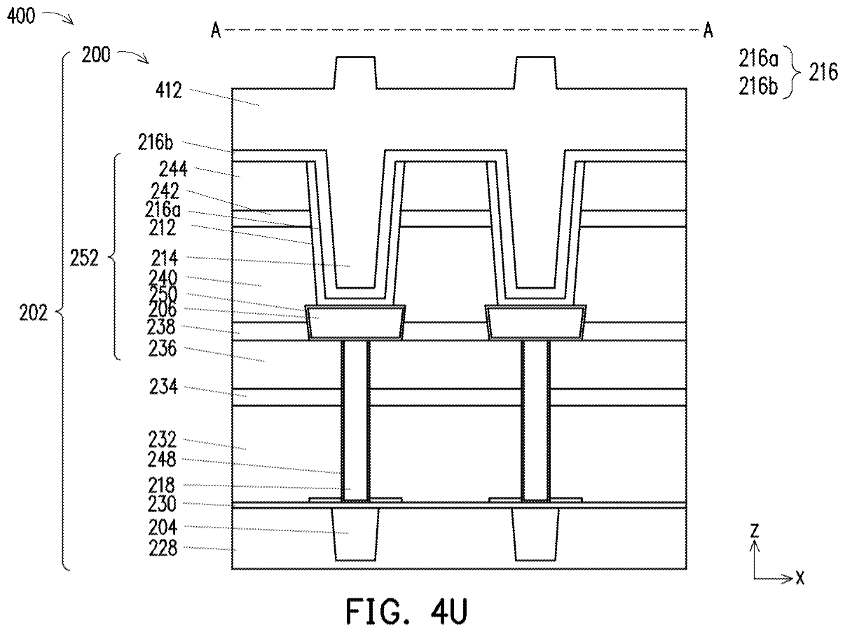

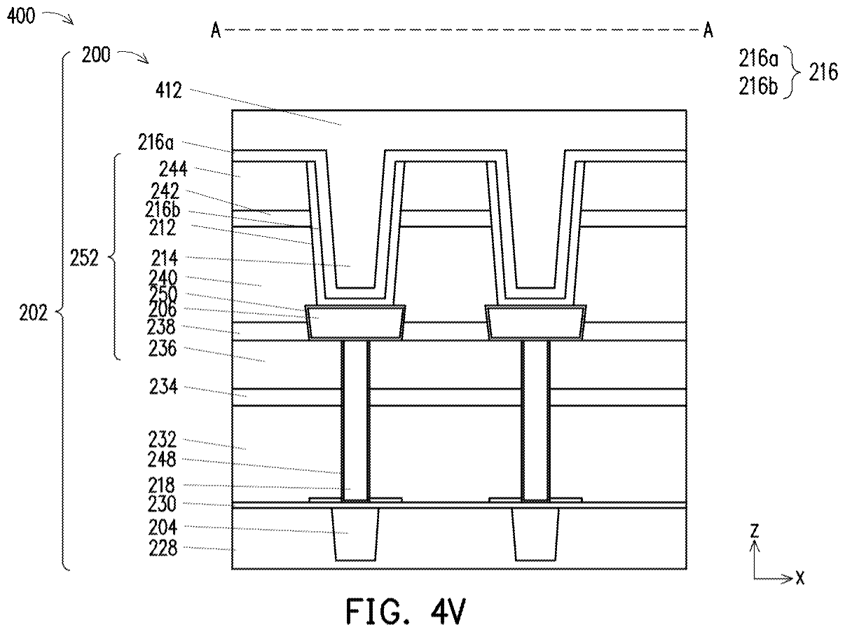

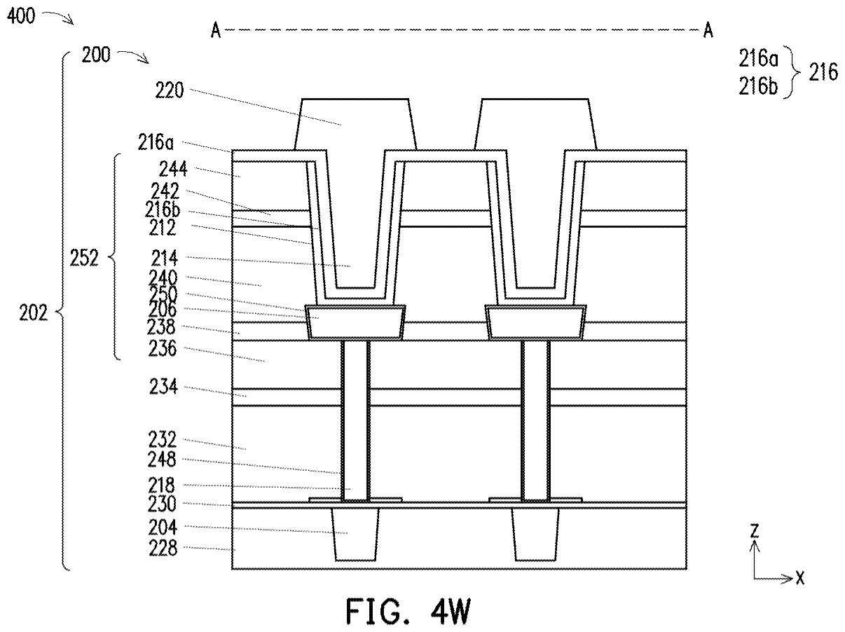

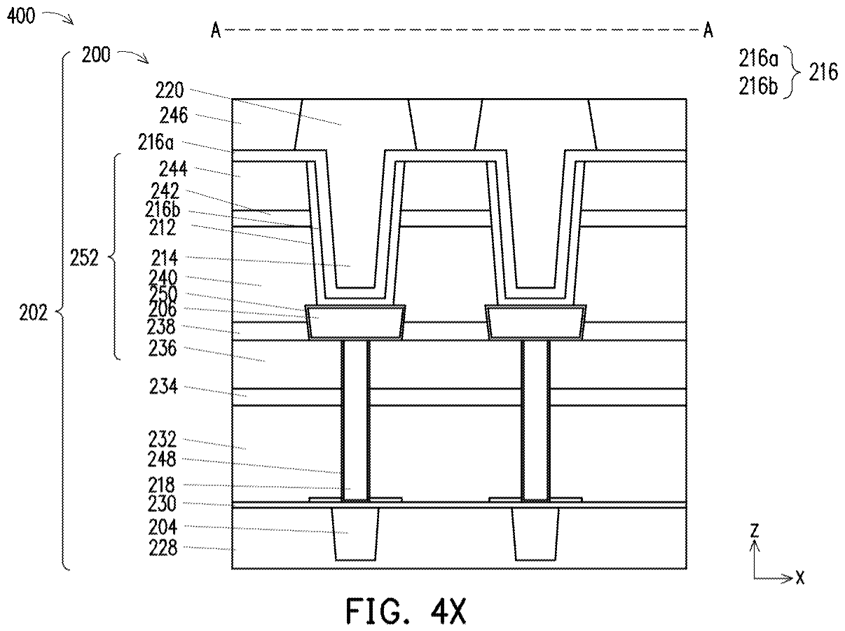

In some implementations, one or more of the semiconductor processing tools 102-112 and/or the wafer/die transport tool 114 may be used to perform one or more semiconductor processing operations described herein. For example, one or more of the semiconductor processing tools 102-112 and/or the wafer/die transport tool 114 may be used to form, in a semiconductor device, a first source/drain region of a memory cell structure; form a plurality of dielectric layers over the first source/drain region; form, in the plurality of dielectric layers, a first source/drain interconnect and a second source/drain interconnect; form a conductive layer over the plurality of dielectric layers and on the first source/drain interconnect and the second source/drain interconnect; form, in the plurality of dielectric layers and through the conductive layer, a recess between the first source/drain interconnect and the second source/drain interconnect, where forming the recess through the conductive layer results in formation of a second source/drain region above the first source/drain interconnect and a third source/drain region above the second source/drain interconnect; form a channel layer on sidewalls and a bottom surface of the recess; form a gate dielectric layer on the channel layer in the recess; and/or form a gate electrode on the gate dielectric layer, among other examples. In some implementations, one or more of the semiconductor processing tools 102-112 and/or the wafer/die transport tool 114 may be used to perform one or more semiconductor processing operations described in connection with FIGS. 4A-4X, 6A-6F, 8A-8D, 10A-10D, and/or 12, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

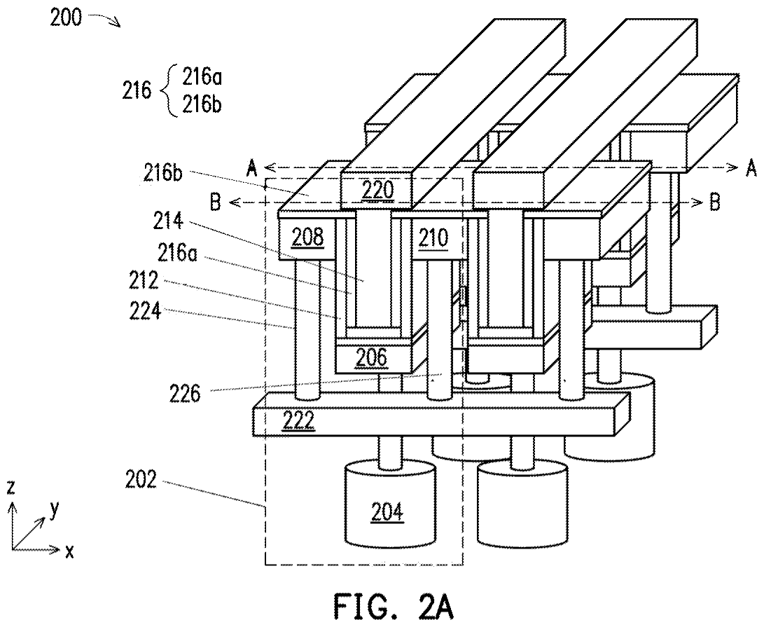

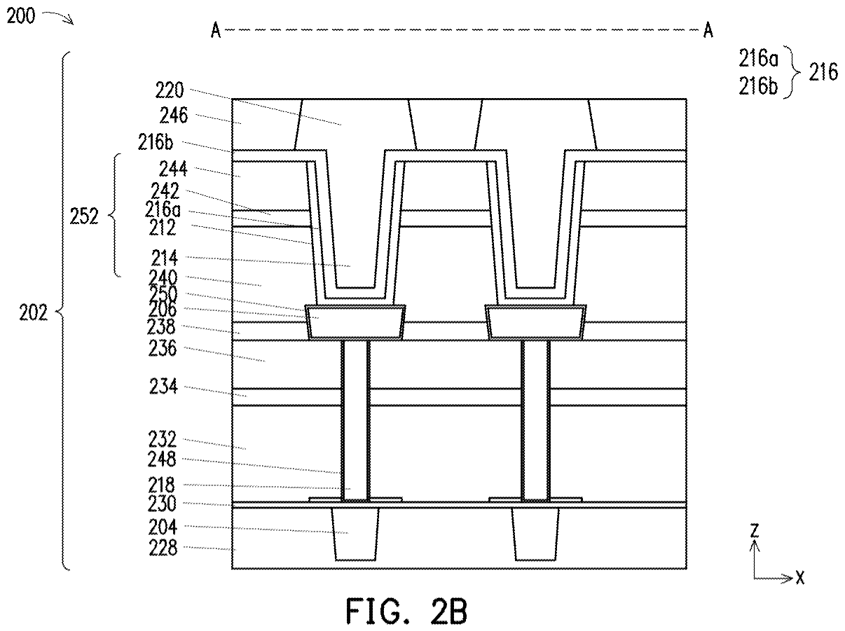

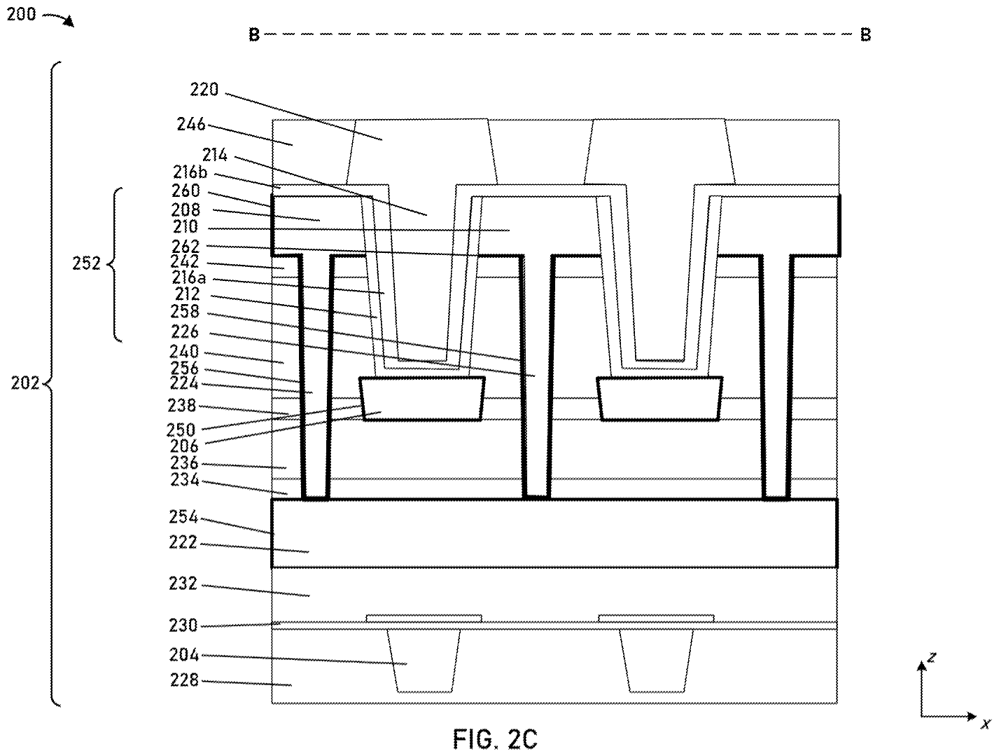

FIGS. 2A-2C are diagrams of an example semiconductor device 200 described herein. The semiconductor device 200 may include a semiconductor memory device or another type of semiconductor device that includes one or more memory cell structures 202. In some implementations, the semiconductor device 200 includes a plurality of memory cell structures 202 that are arranged in a grid as a memory cell array. A memory cell structure 202 may correspond to a 1T-1X memory cell in the memory cell array.

FIG. 2A illustrates a perspective view of the memory cell structure 202. A memory cell structure 202 includes a storage structure 204 coupled with a transistor structure. The storage structure 204 includes a capacitor structure (e.g., a deep trench capacitor (DTC) structure, a thin film capacitor structure), a ferroelectric storage structure, a resistive storage structure, a phase change material storage structure, and/or another type of storage structure that is capable of being configured in two or more states corresponding to or more logical values.

The storage structure 204 is electrically coupled with a source/drain region 206 of the memory cell structure 202. “Source/drain region” may refer to a source or a drain, individually or collectively, depending upon the context. The source/drain region 206 is located above the storage structure 204 such that the storage structure and the source/drain region 206 are vertically arranged in a z-direction in the semiconductor device 200. The z-direction may be approximately perpendicular to a substrate and/or one or more backend dielectric layers of the semiconductor device 200.

The memory cell structure 202 further includes one or more source/drain regions 208 and/or 210 above the source/drain region 206 in the z-direction. A channel layer 212 of the memory cell structure 202 is located between a gate electrode 214 and the source/drain regions 208 and/or 210. The source/drain regions 208 and 210 are located to a sidewall of the gate electrode 214 on opposing sides of the gate electrode 214, and the source/drain region 206 is located under a bottom surface of the gate electrode 214.

The gate electrode 214 includes an elongated structure in the z-direction. The gate electrode 214 extends between the source/drain region 206 and the source/drain region 208 (and/or between the source/drain region 206 and the source/drain region 210) in the z-direction, and may therefore be referred to as a vertical gate. The channel layer 212 may be a U-shaped layer such that the channel layer 212 is on two or more sidewalls of the gate electrode 214 and on a bottom surface of the gate electrode 214. The U-shape of the channel layer 212 creates a U-shaped channel through which an electrical current to flow between the source/drain region 206 and the source/drain region 208, and between the source/drain region 206 and the source/drain region 210, while minimizing the flow of the electrical current in other directions. This increases the efficiency of the memory cell structure 202 and reduces current leakage in the memory cell structure 202.

The channel extends between the source/drain region 206 and the source/drain region 208 in the z-direction, and/or between the source/drain region 206 and the source/drain region 210 in the z-direction. Thus, the gate length and the channel length of the transistor of the memory cell structure 202 are dimensions in the z-direction. The source/drain regions 208 and 210 are in direct physical contact with the portions of the channel layer 212 on the sidewalls of the gate electrode 214. The source/drain region 206 is in direct physical contact with the portion of the channel layer 212 under the bottom surface of the gate electrode 214.

The memory cell structure 202 further includes a gate dielectric layer 216. The gate dielectric layer 216 is located between the channel layer 212 and the gate electrode 214. A portion 216a of the gate dielectric layer 216 is arranged in a similar manner as the channel layer 212. For example, the portion 216a of the gate dielectric layer 216 is a U-shaped layer. The portion 216a of the gate dielectric layer 216 is located between the gate electrode 214 and the source/drain regions 208 and 210. The portion 216a of the gate dielectric layer 216 is also located under the bottom surface of the gate electrode 214 such that the portion 216a of the gate dielectric layer 216 is located between the bottom surface of the gate electrode 214 and the source/drain region 206.

The gate dielectric layer 216 further includes a portion 216b that extends in the x-y plane in the semiconductor device 200 such that the portion 216b of the gate dielectric layer 216 is located over top surfaces of the source/drain regions 208 and/or 210. The portion 216b of the gate dielectric layer 216 is in direct physical contact with the top surfaces of the source/drain regions 208 and/or 210. The portion 216b of the gate dielectric layer 216 extends laterally outward from a portion 216a of the gate dielectric layer 216, and may extend in an x-direction across a plurality of memory cell structures 202, as shown in the example in FIG. 2A.

The memory cell structure 202 includes a source/drain interconnect 218 that electrically couples the storage structure 204 and the source/drain region 206. The source/drain interconnect 218 may include a via, a column, a pillar, and/or another type of elongated structure in the z-direction.

The gate electrode 214 may be electrically coupled and/or physically coupled with a word line conductive structure 220 of the semiconductor device 200. In some implementations, the word line conductive structure 220 extends in a y-direction in the semiconductor device 200, which is approximately perpendicular to the x-direction and the z-direction. Additionally and/or alternatively, the word line conductive structure 220 extends in the x-direction. The word line conductive structure 220 may include a metallization layer, a trench, a conductive trace, and/or another type of conductive structure.

The source/drain regions 208 and/or 210 may be electrically coupled with a bit line conductive structure 222 through a source/drain interconnect 224 and/or a source/drain interconnect 226, respectively. The source/drain interconnects 224 and 226 may each include a via, a column, a pillar, and/or another type of elongated structure in the z-direction. The bit line conductive structure 222 extends in the x-direction in the semiconductor device 200. Additionally and/or alternatively, the bit line conductive structure 222 extends in the y-direction. The bit line conductive structure 222 may include a metallization layer, a trench, a conductive trace, and/or another type of conductive structure. The word line conductive structure 220 and the bit line conductive structure 222 may each be coupled with circuitry, including control circuitry, a read buffer, a write buffer, and/or another type of circuitry in the semiconductor device 200.

FIG. 2B illustrates a cross-section view of the memory cell structure 202 along the line A-A in FIG. 2A, which is located through a center of the gate electrode 214. As shown in FIG. 2B, the memory cell structure 202 may be included in a plurality of backend dielectric layers of the semiconductor device 200. The plurality of backend dielectric layers may be located in a back end of line (BEOL) region of the semiconductor device 200. In some implementations, the memory cell structure 202 may be located in another region of the semiconductor device 200, such as a front end of line (FEOL) region of the semiconductor device 200.

The plurality of backend dielectric layers may include a dielectric layer 228, an etch stop layer (ESL) 230 above the dielectric layer 228, a dielectric layer 232 above the ESL 230, an ESL 234 above the dielectric layer 232, a dielectric layer 236 above the ESL 234, an ESL 238 above the dielectric layer 236, a dielectric layer 240 above the ESL 238, an ESL 242 above the dielectric layer 240, a dielectric layer 244 above the ESL 242, and/or a dielectric layer 246 above the dielectric layer 244, among other examples. The dielectric layers 228, 232, 240, 244, and 246, and the ESLs 230, 234, 238, and 242 may each include one or more dielectric materials. Examples of dielectric materials include an oxide, a nitride, a silicon oxide (SiOₓ), a silicon nitride (SiₓN_{y}), a silicon oxynitride (SiON), fluoride-doped silicate glass (FSG), a low dielectric constant (low-k) dielectric material (e.g., a dielectric material having a dielectric constant of less than 3.9), a high dielectric constant (high-k) dielectric material (e.g., a dielectric material having a dielectric constant of greater than 3.9), and/or another suitable dielectric material.

The storage structure 204 may be included in the dielectric layer 228 and may extend through the ESL 230. The source/drain interconnect 218 may be coupled with a top surface of the storage structure 204 and may extend through the dielectric layer 232, the ESL 234, and/or the dielectric layer 236, among other examples. The source/drain interconnect 218 may include one or more electrically conductive materials, such as tungsten (W), cobalt (Co), ruthenium (Ru), titanium (Ti), aluminum (Al), copper (Cu), gold (Au), an alloy thereof, and/or a combination thereof, among other examples of conductive materials.

One or more liner layers 248 may be included between the source/drain interconnect 218 and the dielectric layers 232, 236, and the ESL 234. The liner layer(s) 248 may include adhesion liners (e.g., liners that are included to promote adhesion between the source/drain interconnect 218 and the surrounding layers), barrier layers (e.g., layers that are included to reduce or minimize diffusion of the material of the source/drain interconnect 218 into the surrounding layers), and/or another type of liner layers. Examples of materials for the liner layer(s) 248 include tantalum nitride (TaN) and/or titanium nitride (TiN), among other examples.

The source/drain region 206 may be located on the source/drain interconnect 218 such that the source/drain region 206 is electrically coupled and/or physically coupled with the source/drain interconnect 218. The source/drain region 206 may be located in dielectric layer 240 and may extend through the ESL 238. The source/drain region 206 may include polysilicon, copper (Cu), cobalt (Co), ruthenium (Ru), titanium (Ti), tungsten (W), and/or aluminum (Al), among other examples.

One or more liner layers 250 may be located between the source/drain region 206 and the dielectric layer 240 and/or the ESL 238. The liner layer(s) 250 may include a barrier liner to prevent material migration from the source/drain region 206 into the surrounding layers, an adhesion layer to promote adhesion between the source/drain region 206 and the surrounding layers, and/or another type of liner layer. Examples of liner layer(s) 250 include tantalum nitride (TaN), titanium nitride (TiN), and/or another suitable liner layer, among other examples.

The gate electrode 214 extends through the dielectric layer 244, through the ESL 242, and/or through the dielectric layer 240. The gate electrode 214 is on the source/drain region 206. The gate electrode 214 may include polysilicon, copper (Cu), cobalt (Co), ruthenium (Ru), titanium (Ti), tungsten (W), and/or aluminum (Al), among other examples. The channel layer 212 and the portion 216a of the gate dielectric layer are included between the gate electrode 214 and the dielectric layer 240, between the gate electrode 214 and the ESL 242, between the gate electrode 214 and the dielectric layer 244, and/or and between the gate electrode 214 and the source/drain region 206. The portion 216b of the gate dielectric layer 216 may be included between the dielectric layer 244 and the dielectric layer 246.

In some implementations, the channel layer 212 includes a semiconductor material such as silicon (Si), among other examples. In some implementations, the channel layer 212 may include one or more metal-oxide materials or metal-oxide semiconductor materials. In some implementations, the channel layer 212 is an n-type channel that includes tin oxide (SnOₓ such as SnO₂), indium oxide (InₓO_{y} such as In₂O₃), zinc oxide (ZnO), indium gallium zinc oxide (InGaZnO or IGZO), indium tin oxide (ITO), and/or another n-type metal-oxide material. In some implementations, the channel layer 212 is a p-type channel that includes nickel oxide (NiO), copper oxide (CuₓO such as Cu₂O), copper aluminum oxide (CuAlOₓ such as CuAlO₂), copper gallium oxide (CuGaOₓ such as CuGaO₂), copper indium oxide (CuInOₓ such as CuInO₂), strontium cuprate (SrCuₓO_{y} such as SrCu₂O₂), tin oxide (SnO), and/or another p-type metal-oxide material.

The gate dielectric layer 216 may include one or more dielectric materials, such as hafnium oxide (HfOₓ such as HfO₂), silicon oxide (SiOₓ such as SiO₂), aluminum oxide (AlₓO_{y} such as Al₂O₃), zirconium oxide (ZrₓO_{y}), titanium oxide (TiₓO_{y}), and/or silicon oxynitride (SiON), among other examples.

The source/drain region 206, the gate electrode 214, the channel layer 212, and the gate dielectric layer 216 may be a part of a transistor structure 252 of the memory cell structure 202. The source/drain region 206 of the transistor structure 252 is electrically coupled with the storage structure 204 of the memory cell structure 202 (e.g., through the source/drain interconnect 218). The storage structure 204 is located under the transistor structure 252 in the z-direction.

The gate electrode 214 of the transistor structure 252 is electrically coupled and/or physically coupled with the word line conductive structure 220 above the transistor structure 252 in the z-direction. The word line conductive structure 220 may be located in the dielectric layer 246 and may be on a top surface of the gate electrode 214. The word line conductive structure 220 may include one or more electrically conductive materials, such as tungsten (W), cobalt (Co), ruthenium (Ru), titanium (Ti), aluminum (Al), copper (Cu), gold (Au), an alloy thereof, and/or a combination thereof, among other examples of conductive materials.

FIG. 2C illustrates a cross-section view of the memory cell structure 202 along the line B-B in FIG. 2A, which is located adjacent to a side of the gate electrode 214. As shown in FIG. 2C, the transistor structure 252 further includes the source/drain region 208 and/or the source/drain region 210. The source/drain region 208 and the source/drain region 210 may be located in the dielectric layer 244, and may be electrically coupled with the bit line conductive structure 222 through the source/drain interconnect 224 and the source/drain interconnect 226 respectively. The source/drain regions 208 and/or 210 may be in direct physical contact with the channel layer 212 on opposing sidewalls of the gate electrode 214. The portion 216b of the gate dielectric layer 216 may be located in direct physical contact with the top surfaces of the source/drain regions 208 and/or 210. In some implementations, the source/drain region 210 and the source/drain interconnect 226 are omitted from the memory cell structure 202. The source/drain region 208 and/or the source/drain region 210 may each include polysilicon, copper (Cu), cobalt (Co), ruthenium (Ru), titanium (Ti), tungsten (W), and/or aluminum (Al), among other examples.

The source/drain interconnects 224 and 226 may be located in and may extend through the ESL 234, the dielectric layer 236, the ESL 238, the dielectric layer 240, and/or the ESL 242. The source/drain interconnect 224 and/or the source/drain interconnect 226 may each include one or more electrically conductive materials, such as tungsten (W), cobalt (Co), ruthenium (Ru), titanium (Ti), aluminum (Al), copper (Cu), gold (Au), an alloy thereof, and/or a combination thereof, among other examples of conductive materials.

The bit line conductive structure 222 may be located in and/or above the dielectric layer 232. The bit line conductive structure 222 may include one or more electrically conductive materials, such as tungsten (W), cobalt (Co), ruthenium (Ru), titanium (Ti), aluminum (Al), copper (Cu), gold (Au), an alloy thereof, and/or a combination thereof, among other examples of conductive materials.

One or more liner layers 254 may be included between the bit line conductive structure 222 and the dielectric layer 232. The liner layer(s) 254 may include adhesion liners (e.g., liners that are included to promote adhesion between the bit line conductive structure 222 and the surrounding layers), barrier layers (e.g., layers that are included to reduce or minimize diffusion of the material of the bit line conductive structure 222 into the surrounding layers), and/or another type of liner layers. Examples of materials for the liner layer(s) 250 include tantalum nitride (TaN) and/or titanium nitride (TiN), among other examples.

One or more liner layers 256 may be included between the source/drain interconnect 224 and the dielectric layers 236 and/or 240, and/or between the source/drain interconnect 224 and the ESLs 234, 238, and/or 242. The liner layer(s) 256 may include adhesion liners (e.g., liners that are included to promote adhesion between the source/drain interconnect 224 and the surrounding layers), barrier layers (e.g., layers that are included to reduce or minimize diffusion of the material of the source/drain interconnect 224 into the surrounding layers), and/or another type of liner layers. Examples of materials for the liner layer(s) 256 include tantalum nitride (TaN) and/or titanium nitride (TiN), among other examples.

One or more liner layers 258 may be included between the source/drain interconnect 226 and the dielectric layers 236 and/or 240, and/or between the source/drain interconnect 226 and the ESLs 234, 238, and/or 242. The liner layer(s) 258 may include adhesion liners (e.g., liners that are included to promote adhesion between the source/drain interconnect 226 and the surrounding layers), barrier layers (e.g., layers that are included to reduce or minimize diffusion of the material of the source/drain interconnect 226 into the surrounding layers), and/or another type of liner layers. Examples of materials for the liner layer(s) 258 include tantalum nitride (TaN) and/or titanium nitride (TiN), among other examples.

One or more liner layers 260 may be included between the source/drain region 208 and the dielectric layer 244 and/or between the source/drain region 208 and the ESL 242. The liner layer(s) 260 may include adhesion liners (e.g., liners that are included to promote adhesion between the source/drain region 208 and the surrounding layers), barrier layers (e.g., layers that are included to reduce or minimize diffusion of the material of the source/drain region 208 into the surrounding layers), and/or another type of liner layers. Examples of materials for the liner layer(s) 260 include tantalum nitride (TaN) and/or titanium nitride (TiN), among other examples.

One or more liner layers 262 may be included between the source/drain region 210 and the dielectric layer 244 and/or between the source/drain region 210 and the ESL 242. The liner layer(s) 262 may include adhesion liners (e.g., liners that are included to promote adhesion between the source/drain region 210 and the surrounding layers), barrier layers (e.g., layers that are included to reduce or minimize diffusion of the material of the source/drain region 210 into the surrounding layers), and/or another type of liner layers. Examples of materials for the liner layer(s) 262 include tantalum nitride (TaN) and/or titanium nitride (TiN), among other examples.

As indicated above, FIGS. 2A-2C are provided as an example. Other examples may differ from what is described with regard to FIGS. 2A-2C.

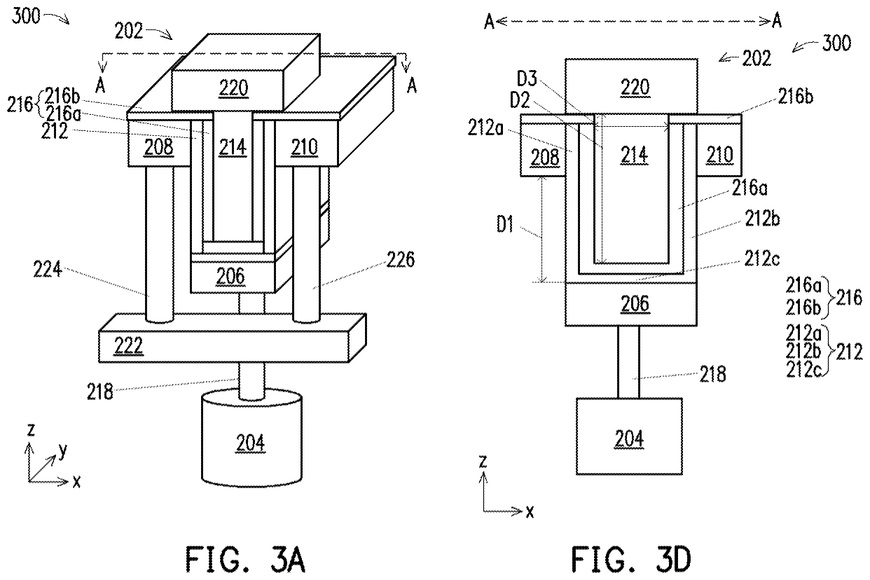

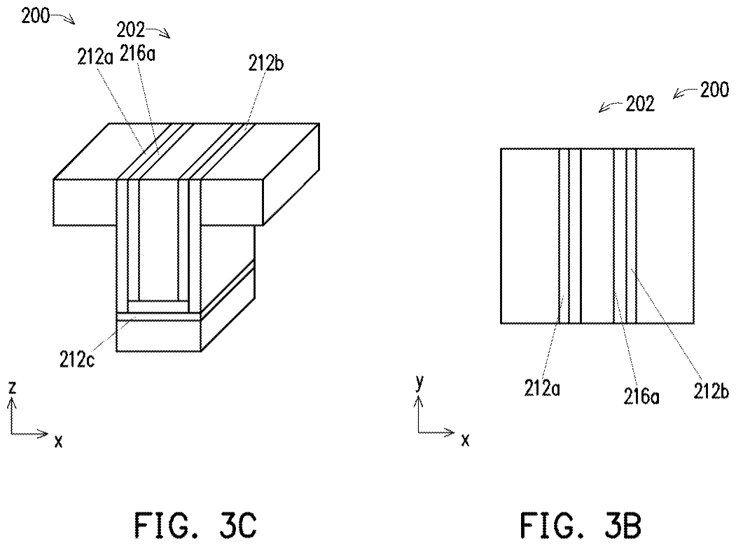

FIGS. 3A-3D are diagrams of an example implementation 300 of a memory cell structure 202 described herein. FIG. 3A illustrates a perspective view of the example implementation 300 of a memory cell structure 202. FIG. 3B illustrates a cross-section view of the example implementation 300 of a memory cell structure 202 along the line A-A in FIG. 3A, which is located through a center of the gate electrode 214 of the memory cell structure 202.

As shown in FIG. 3A, the gate electrode 214 includes an elongated structure in the z-direction. The gate electrode 214 extends between the source/drain region 206 and the source/drain region 208 (and/or between the source/drain region 206 and the source/drain region 210) in the z-direction, and may therefore be referred to as a vertical gate. The gate electrode 214 may include an approximately rectangular prism shape. The channel layer 212 is included on the sidewalls of the gate electrode 214 between the gate electrode 214 and the source/drain regions 208 and 210 to form an approximately U-shaped channel.

As shown in FIG. 3B, the U-shaped layer of the channel layer 212 includes a sidewall segment 212a extending between the source/drain region 206 and the source/drain region 208 in the z-direction, a sidewall segment 212b between the source/drain region 206 and the source/drain region 210 in the z-direction, and a bottom segment 212c between the bottom surface of the gate electrode 214 and the source/drain region 206. The sidewall segments 212a and 212b connect to opposing ends of the bottom segment 212c to form the U-shaped layer. The channel length (L_{g}—indicated in FIG. 3B as dimension D1) of the transistor of the memory cell structure 202 may be increased in the z-direction without (or with minimal) increase in the x-direction and/or y-direction size of the memory cell structure 202 by increasing the z-direction length of the sidewall segments 212a and 212b of the channel layer 212.

In some implementations, the channel length (the dimension D1 in the z-direction) is included in a range of approximately 25 nanometers to approximately 50 nanometers. Selecting the channel length to be less than approximately 25 nanometers may result in threshold voltage roll-off, which may induce increased leakage in the transistor of the memory cell structure 202. Selecting the channel to be greater than approximately 50 nanometers may result in insufficient drive current for programming and/or erasing the storage structure 204. If the channel length is included in the range of approximately 25 nanometers to approximately 50 nanometers, a low current leakage may be achieved for the transistor without sacrificing the drive current for programming and/or erasing the storage structure 204. However, other values for the channel length, and ranges other than approximately 25 nanometers to approximately 50 nanometers, are within the scope of the present disclosure.

As further shown in FIG. 3B, another example dimension D2 of the memory cell structure 202 includes an x-direction (or a y-direction) width of the gate electrode 214. In some implementations, the dimension D2 is at least approximately 30 nanometers and is not greater than a distance between the sidewall segments 212a and 212b of the channel layer 212. If the dimension D2 is less than approximately 30 nanometers, voids may occur in the gate electrode 214 because of insufficient gap-filling performance when forming the gate electrode 214. However, other values and ranges for the dimension D2 are within the scope of the present disclosure.

As further shown in FIG. 3B, another example dimension D3 of the memory cell structure 202 includes a z-direction thickness of the gate electrode 214. In some implementations, the dimension D3 is included in a range of approximately 40 nanometers to approximately 85 nanometers. If the dimension D3 is less than approximately 40 nanometers, the word line conductive structure 220 may be unable to land on the gate electrode 214. If the dimension D3 is greater than approximately 85 nanometers, voids may occur in the gate electrode 214 because of insufficient gap-filling performance when forming the gate electrode 214. If the dimension D3 is included in the range of approximately 40 nanometers to approximately 85 nanometers, the word line conductive structure 220 may be formed on the gate electrode 214 while reducing the likelihood of void formation in the gate electrode 214. However, other values for the dimension D3, and ranges other than approximately 40 nanometers to approximately 85 nanometers, are within the scope of the present disclosure.

Other example dimensions of the memory cell structure 202 include a z-direction thickness of the source/drain regions 208 and/or 210 and an extension distance of the gate electrode 214 above the portion 216a of the gate dielectric layer 216. In some implementations, the thickness of the source/drain regions 208 and/or 210 may be included in a range of approximately 15 nanometers to approximately 30 nanometers to enable a sufficiently high planarization uniformity to be achieved for the source/drain regions 208 and/or 210 while enabling sufficient gap-filling performance to be achieved for the gate electrode 214. However, other values for the range are within the scope of the present disclosure. In some implementations, the extension distance of the gate electrode 214 above the portion 216a of the gate dielectric layer 216 is included in a range of greater than 0 nanometers to approximately 5 nanometers to enable the word line conductive structure 220 to be formed on the gate electrode 214. However, other values for the range are within the scope of the present disclosure.

FIGS. 3C and 3D illustrate a detailed view of the channel layer 212 of the memory cell structure 202 in the example implementation 300. FIG. 3C illustrates a perspective view of the channel layer 212, and FIG. 3D illustrates a top-down view of the channel layer. As shown in FIGS. 3C and 3D, the source/drain region 208 may be in direct physical contact with the sidewall segment 212a of the channel layer. The source/drain region 210 may be in direct physical contact with the sidewall segment 212b of the channel layer. The source/drain region 206 may be in direct physical contact with the bottom segment 212c of the channel layer.

The portion 216a of the gate dielectric layer 216 may be located between the sidewall segment 212a and the gate electrode 214. The portion 216a of the gate dielectric layer 216 may be located between the sidewall segment 212b and the gate electrode 214. The portion 216a of the gate dielectric layer 216 may be located between the bottom segment 212c and the gate electrode 214.

As indicated above, FIGS. 3A-3D are provided as an example. Other examples may differ from what is described with regard to FIGS. 3A-3D.

FIGS. 4A-4X are diagrams of an example implementation 400 of forming a memory cell structure 202 described herein. In some implementations, one or more of the semiconductor processing operations described in connection with FIGS. 4A-4X may be performed using one or more of the semiconductor processing tools 102-112 described herein. In some implementations, one or more of the semiconductor processing operations described in connection with FIGS. 4A-4X may be performed using another semiconductor processing tool. Some of FIGS. 4A-4X are illustrated from the cross-section view along the line-A-A in FIG. 2A, and some of FIGS. 4A-4X are illustrated from the cross-section view along the line-B-B in FIG. 2A.

Turning to FIG. 4A, the dielectric layer 228 may be formed in the semiconductor device 200. The ESL 230 may be formed over and/or on the dielectric layer 228. The storage structure 204 may be formed through the ESL 230 and in the dielectric layer 228. The dielectric layer 232 may be formed over and/or on the ESL 230 and over and/or on the storage structure 204. The dielectric layer 228, the ESL 230, and the dielectric layer 232 may be arranged in the z-direction in the semiconductor device 200. The top surfaces of the dielectric layer 228, the ESL 230, and the dielectric layer 232 may extend in the x-direction and in the y-direction in the semiconductor device 200.

A deposition tool 102 may be used to deposit the dielectric layer 228, the ESL 230, and/or the dielectric layer 232 using a PVD technique, an ALD technique, a CVD technique, another type of deposition technique described in connection with FIG. 1, and/or another suitable deposition technique. In some implementations, a planarization tool 110 is used to planarize the dielectric layer 228, the ESL 230, and/or the dielectric layer 232 after the dielectric layer 228, the ESL 230, and/or the dielectric layer 232 are formed.

In some implementations, forming the storage structure 204 includes forming a capacitor structure in the dielectric layer 228. The capacitor structure may include a thin film capacitor structure (e.g., a planar capacitor structure), a DTC structure, and/or another type of capacitor structure. The capacitor structure may have a metal-insulator-metal (MIM) arrangement in which a bottom electrode and a top electrode are separated by an insulator layer. Additionally and/or alternatively, forming the storage structure 204 may include forming a phase-change material structure, forming a resistive structure, forming a ferroelectric structure, and/or forming another type of storage structure.

As shown in FIG. 4B, the bit line conductive structure 222 is formed in and/or on the dielectric layer 228. Forming the bit line conductive structure 222 may include forming the liner layer(s) 254, and forming the bit line conductive structure 222 on the liner layer(s) 254. In some implementations, an etch tool 108 is used to etch the dielectric layer 228 and/or 232 to form a trench in which the bit line conductive structure 222 is formed. A deposition tool 102 may be used to deposit the liner layer(s) 254 using a PVD technique, an ALD technique, a CVD technique, another type of deposition technique described in connection with FIG. 1, and/or another suitable deposition technique. A deposition tool 102 and/or a plating tool 112 may be used to deposit the bit line conductive structure 222 using a CVD technique, a PVD technique, an ALD technique, an electroplating technique, another deposition technique described above in connection with FIG. 1, and/or another suitable deposition technique. In some implementations, a seed layer is first deposited on the liner layer(s) 254, and the bit line conductive structure 222 is deposited on the seed layer. In some implementations, a planarization tool 110 is used to planarize the bit line conductive structure 222 after the bit line conductive structure 222 is formed.

As shown in FIGS. 4C and 4D, the ESL 234 may be formed over and/or on the dielectric layer 232 (as shown in FIG. 4C) and over and/or on the bit line conductive structure 222 (as shown in FIG. 4D). The dielectric layer 236 may be formed over and/or the ESL 234. A deposition tool 102 may be used to deposit the ESL 234 and/or the dielectric layer 236 using a PVD technique, an ALD technique, a CVD technique, another type of deposition technique described in connection with FIG. 1, and/or another suitable deposition technique. In some implementations, a planarization tool 110 is used to planarize the ESL 234 and/or the dielectric layer 236 after the ESL 234 and/or the dielectric layer 236 are formed.

As shown in FIG. 4E, a recess 402 is formed through the dielectric layer 236, through the ESL 234, and through the dielectric layer 232 to the storage structure 204. The recess 402 may be formed in the z-direction in the semiconductor device 200 such that the recess 402 extends from a top surface of the dielectric layer 236 to a top surface of the storage structure 204. The top surface of the storage structure 204 may be exposed through the recess 402.

In some implementations, a pattern in a photoresist layer is used to etch the dielectric layer 236, the ESL 234, and/or the dielectric layer 232 to form the recess 402. In these implementations, a deposition tool 102 may be used to form the photoresist layer on the dielectric layer 236. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 236, the ESL 234, and/or the dielectric layer 232 based on the pattern to form the recess 402. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 402 based on a pattern.

As shown in FIG. 4F, the liner layer(s) 248 are formed on sidewalls and on a bottom surface of the recess 402 (where the bottom surface of the recess 402 may correspond to the top surface of the storage structure 204). The liner layer(s) 248 may be conformally deposited such that the liner layer(s) 248 conform to a profile of the recess 402. A deposition tool 102 may be used to deposit the liner layer(s) 248 using a PVD technique, an ALD technique, a CVD technique, another type of deposition technique described in connection with FIG. 1, and/or another suitable deposition technique.

As further shown in FIG. 4F, the recess 402 may be filled with the source/drain interconnect 218 on the liner layer(s) 248. The source/drain interconnect 218 extends in the z-direction through the dielectric layer 232, the ESL 234, and/or the dielectric layer 236. A deposition tool 102 and/or a plating tool 112 may be used to deposit the source/drain interconnect 218 using a CVD technique, a PVD technique, an ALD technique, an electroplating technique, another deposition technique described above in connection with FIG. 1, and/or another suitable deposition technique. In some implementations, a seed layer is first deposited on the liner layer(s) 248, and the source/drain interconnect 218 is deposited on the seed layer. In some implementations, a planarization tool 110 is used to planarize the top surface of the dielectric layer 236 and/or the source/drain interconnect 218 after the source/drain interconnect 218 is formed.

As shown in FIG. 4G, the ESL 238 may be formed over and/or on the dielectric layer 236 and/or over and/or on the source/drain interconnect 218. The dielectric layer 240 may be formed over and/or on the ESL 238. A deposition tool 102 may be used to deposit the ESL 238 and/or the dielectric layer 240 using a PVD technique, an ALD technique, a CVD technique, another type of deposition technique described in connection with FIG. 1, and/or another suitable deposition technique. In some implementations, a planarization tool 110 is used to planarize the ESL 238 and/or the dielectric layer 240 after the ESL 238 and/or the dielectric layer 240 are formed.

As shown in FIG. 4H, the source/drain region 206 and the associated liner layer(s) 250 are formed over and/or on the source/drain interconnect 218. The source/drain region 206 and the associated liner layer(s) 250 may be formed in and/or through the dielectric layer 240 and/or the ESL 238.

To form the source/drain region 206 and the associated liner layer(s) 250, a recess may be formed through the dielectric layer 240 and/or through the ESL 238 to the source/drain interconnect 218. The top surface of the source/drain interconnect 218 is exposed through the recess. The recess may be formed in the z-direction from the top surface of the dielectric layer 240 to the top surface of the source/drain interconnect 218.

In some implementations, a pattern in a photoresist layer is used to etch the dielectric layer 240 and/or the ESL 238 to form the recess. In these implementations, a deposition tool 102 may be used to form the photoresist layer on the dielectric layer 240. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 240 and/or the ESL 238 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

The liner layer(s) 250 may be formed on sidewalls and on a bottom surface of the recess. The liner layer(s) 250 may be conformally deposited such that the liner layer(s) 250 conform to a profile of the recess. The liner layer(s) 250 may also be formed on the top surface of the dielectric layer 240. A deposition tool 102 may be used to deposit the liner layer(s) 250 using a PVD technique, an ALD technique, a CVD technique, another type of deposition technique described in connection with FIG. 1, and/or another suitable deposition technique.

The recess may then be filled with the source/drain region 206 on the liner layer(s) 250. In this way, the source/drain region 206 is formed on the source/drain interconnect 218. A deposition tool 102 and/or a plating tool 112 may be used to deposit the source/drain region 206 using a CVD technique, a PVD technique, an ALD technique, an electroplating technique, another deposition technique described above in connection with FIG. 1, and/or another suitable deposition technique. In some implementations, a seed layer is first deposited on the liner layer(s) 250, and the source/drain region 206 is deposited on the seed layer.

As shown in FIG. 4I, a planarization tool 110 may be used to planarize the semiconductor device 200 after the liner layer(s) 250 and the source/drain region 206 are deposited. The planarization tool 110 may be performed to remove material of the liner layer(s) 250 and material of the source/drain region 206 from the top surface of the dielectric layer 240.

As shown in FIG. 4J, additional material of the dielectric layer 240 is deposited after formation of the source/drain region 206. The ESL 242 may be formed over and/or on the dielectric layer 240. The dielectric layer 244 may be formed over and/or on the ESL 242. A deposition tool 102 may be used to deposit the additional material of the dielectric layer 240, the ESL 242, and/or the dielectric layer 244 using a PVD technique, an ALD technique, a CVD technique, another type of deposition technique described in connection with FIG. 1, and/or another suitable deposition technique. In some implementations, a planarization tool 110 is used to planarize the dielectric layer 240, the ESL 242, and/or the dielectric layer 244.

As shown in FIG. 4K, the source/drain interconnect 224 and the associated liner layer(s) 256 are formed in and/or through the dielectric layers 236 and/or 240, and in and/or through the ESLs 234, 238, and/or 242. The source/drain interconnect 226 and the associated liner layer(s) 258 are formed in and/or through the dielectric layers 236 and/or 240, and in and/or through the ESLs 234, 238, and/or 242. A conductive layer 404 and one or more liner layers 406 are formed in the dielectric layer 244 and are coupled with the source/drain interconnects 224 and 226 in a dual damascene configuration.

Recesses may be formed through the dielectric layer 244, through the ESL 242, through the dielectric layer 240, through the ESL 238, through the dielectric layer 236, and/or through the ESL 234 to the bit line conductive structure 222. The recesses may include via portions of a dual damascene profile. Trench portions of the dual damascene profile may be formed in the dielectric layer 244. A deposition tool 102 may be used to form the photoresist layer on the dielectric layer 244. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 244, the ESL 242, the dielectric layer 240, the ESL 238, the dielectric layer 236, and/or the ESL 234 based on the pattern to form the dual damascene profile. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the dual damascene profile based on a pattern.

The liner layer(s) 256, 258, and/or 406 may be conformally deposited such that the liner layer(s) 256, 258, and/or 406 conform to the dual damascene profile. A deposition tool 102 may be used to deposit the liner layer(s) 256, 258, and/or 406 using a PVD technique, an ALD technique, a CVD technique, another type of deposition technique described in connection with FIG. 1, and/or another suitable deposition technique.

The source/drain interconnect 224 may be formed in a via portion of the dual damascene profile on the liner layer(s) 256. The source/drain interconnect 226 may be formed in a via portion of the dual damascene profile on the liner layer(s) 258. The conductive layer 404 may be formed in the trench portion of the dual damascene profile on the liner layer(s) 406. A deposition tool 102 and/or a plating tool 112 may be used to deposit the source/drain interconnect 224, the source/drain interconnect 226, and/or the conductive layer 404 using a CVD technique, a PVD technique, an ALD technique, an electroplating technique, another deposition technique described above in connection with FIG. 1, and/or another suitable deposition technique. In some implementations, a seed layer is first deposited on the liner layer(s) 256, 258, and/or 406, and the source/drain interconnect 224, the source/drain interconnect 226, and/or the conductive layer 404 is deposited on the seed layer. In some implementations, a planarization tool 110 is used to planarize the conductive layer 404.

As shown in FIGS. 4L and 4M, additional material of the dielectric layer 244 is deposited after formation of the source/drain interconnects 224, 226, and the conductive layer 404. A deposition tool 102 may be used to deposit the additional material of the dielectric layer 244 using a PVD technique, an ALD technique, a CVD technique, another type of deposition technique described in connection with FIG. 1, and/or another suitable deposition technique. In some implementations, a planarization tool 110 is used to planarize the dielectric layer 244 after the additional material of the dielectric layer 244 is deposited.

As further shown in FIGS. 4L and 4M, a recess 408 is formed through the dielectric layer 244, through the ESL 242, and through the dielectric layer 240 to the top surface of the source/drain region 206 such that the top surface of the source/drain region 206 is exposed through the recess 408. The recess 408 is also formed through the conductive layer 404 and the liner layer(s) 406. Removal of portions of the conductive layer 404 during formation of the recess 408 results in formation of the source/drain regions 208 and 210 on opposing sides of the recess 408. Similarly, removal of portions of the liner layer(s) 406 during formation of the recess 408 results in formation of the liner layer(s) 260 and 262.

In some implementations, a pattern in a photoresist layer is used to etch the dielectric layer 244, the ESL 242, the dielectric layer 240, and the conductive layer 404 to form the recess 802. In these implementations, a deposition tool 102 may be used to form the photoresist layer on the dielectric layer 244. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 244, the ESL 242, the dielectric layer 240, and the conductive layer 404 based on the pattern to form the recess 408. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 408 based on a pattern.

As shown in FIG. 4N, the channel layer 212 is formed, and the gate dielectric layer 216 is formed on the channel layer 212. The channel layer 212 is formed on sidewalls and on a bottom surface of the recess 408 (where the bottom surface of the recess 408 corresponds to the top surface of the source/drain region 206). Excess material of channel layer 212 may also be formed over and/or on the top surface of the dielectric layer 244. The portion 216a of the gate dielectric layer 216 is formed on the sidewalls and on the bottom surface of the recess 408. A portion 216c of the gate dielectric layer 216 is formed over and/or on the top surface of the dielectric layer 244. A deposition tool 102 may be used to conformally deposit the channel layer 212 and/or the gate dielectric layer 216 using a PVD technique, an ALD technique, a CVD technique, another type of deposition technique described in connection with FIG. 1, and/or another suitable deposition technique. In this way, the channel layer 212 and the portion 216a of the gate dielectric layer 216 conform to the cross-sectional profile of the recess 408. Thus, the channel layer 212 and the portion 216a of the gate dielectric layer 216 on the sidewalls of the recess 408 extend primarily in the z-direction in the semiconductor device 200.

As shown in FIG. 4N, the recess 408 is filled in with a sacrificial layer 410 on the channel layer 212 and on the portion 216a of the gate dielectric layer 216. Excess material of the sacrificial layer 410 is also formed over the portion 216c of the gate dielectric layer 216c. The sacrificial layer 410 includes one or more materials having a high etch selectivity relative to the material(s) of the gate dielectric layer 216. This enables the sacrificial layer 410 to be subsequently removed by etching without (or with minimal) removal of the gate dielectric layer 216. Examples of materials for the sacrificial layer 410 include amorphous silicon (a-Si) and/or a silicon nitride (SiₓN_{y} such as Si₃N₄), among other examples. A deposition tool 102 may be used to deposit the sacrificial layer 410 using a PVD technique, an ALD technique, a CVD technique, another type of deposition technique described in connection with FIG. 1, and/or another suitable deposition technique.

As shown in FIG. 4O, the excess material of the channel layer 212 and the portion 216c of the gate dielectric layer 216 are formed over and/or on the top surfaces of the source/drain regions 208 and 210.

As shown in FIGS. 4P and 4Q, a planarization operation is performed to planarize the sacrificial layer 410, the gate dielectric layer 216, and the channel layer 212. The planarization may stop on the source/drain regions 208 and 210. A planarization tool 110 may be used to perform the planarization operation to remove the excess material of the sacrificial layer 410, to remove the portion 216c of the gate dielectric layer 216, and to remove the excess material of the channel layer 212 from the top surfaces of the source/drain regions 208 and 210.

As shown in FIG. 4R, the sacrificial layer 410 is removed from the recess 408 after the planarization operation. An etch tool 108 may be used to etch the sacrificial layer 410 to remove the sacrificial layer 410 from the semiconductor device 200. An etchant that has a high etch rate for the material of the sacrificial layer 410 and a low etch rate for the material of the gate dielectric layer 216 may be used to etch the sacrificial layer 410. This minimizes the removal of the material of the gate dielectric layer 216 when etching the sacrificial layer 410.

As shown in FIGS. 4S and 4T, additional material of the gate dielectric layer 216 is conformally deposited in the recess 408, on the top surface of the dielectric layer 244, and on the top surfaces of the source/drain regions 208 and 210 after removal of the sacrificial layer 410. A deposition tool 102 may be used to deposit the additional material of the gate dielectric layer 216 using a PVD technique, an ALD technique, a CVD technique, another type of deposition technique described in connection with FIG. 1, and/or another suitable deposition technique. Deposition of the additional material of the gate dielectric layer 216 results in formation of the portion 216b on the top surfaces of the source/drain regions 208 and 210.

As shown in FIG. 4U, the recess 408 is filled in with a conductive layer 412. The conductive layer 412 is formed on the portion 216a of the gate dielectric layer 216 in the recess 408, and on the portion 216b of the gate dielectric layer 216 that is on the dielectric layer 244. A deposition tool 102 and/or a plating tool 112 may be used to deposit the conductive layer 412 using a CVD technique, a PVD technique, an ALD technique, an electroplating technique, another deposition technique described above in connection with FIG. 1, and/or another suitable deposition technique. In some implementations, a seed layer is first deposited on the gate dielectric layer 214 and in the recess 408, and the conductive layer 412 is deposited on the seed layer.

As shown in FIG. 4V, a planarization operation may be performed to planarize the conductive layer 412. A planarization tool 110 may be used to perform the planarization operation.

As shown in FIG. 4W, portions of the conductive layer 412 are removed. Remaining portions of the conductive layer 412 correspond to the gate electrode 214 and the word line conductive structure 220 on the gate electrode 214.

In some implementations, a pattern in a photoresist layer is used to etch the conductive layer 412 to form the gate electrode 214 and the word line conductive structure 220. In these implementations, a deposition tool 102 may be used to form the photoresist layer on the conductive layer 412. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the conductive layer 412 based on the pattern to form the gate electrode 214 and the word line conductive structure 220. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the gate electrode 214 and the word line conductive structure 220 based on a pattern.

As shown in FIG. 4X, the dielectric layer 246 is formed around the word line conductive structure 220. A deposition tool 102 may be used to deposit the dielectric layer 246 using a PVD technique, an ALD technique, a CVD technique, another type of deposition technique described in connection with FIG. 1, and/or another suitable deposition technique. In some implementations, a planarization tool 110 is used to planarize the dielectric layer 246 after the dielectric layer 246 is deposited. In other words, a fill-in operation is performed to fill in the areas around the word line conductive structure 220 with the dielectric layer 246, and then a CMP operation is performed to planarize the dielectric layer 246 (e.g., to be co-planar with the word line conductive structure 220).

As indicated above, FIGS. 4A-4X are provided as an example. Other examples may differ from what is described with regard to FIGS. 4A-4X.

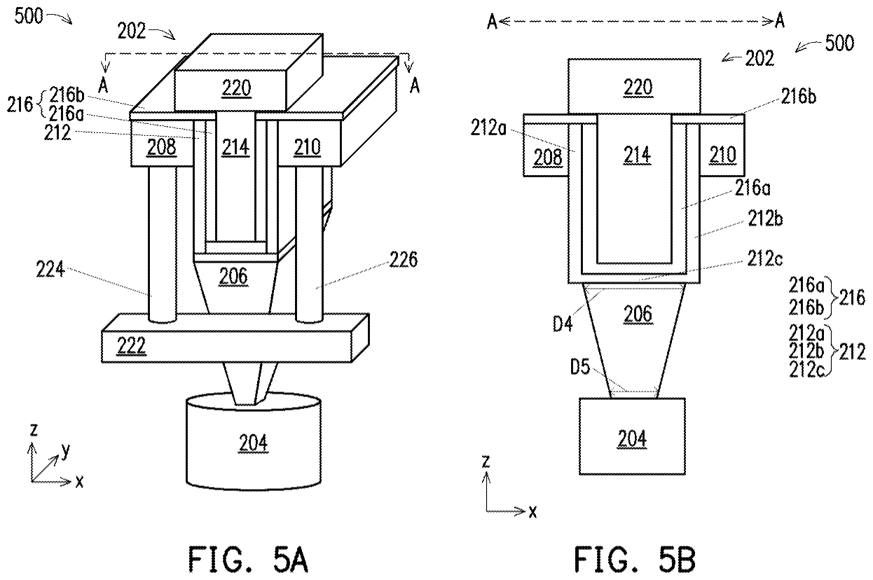

FIGS. 5A and 5B are diagrams of an example implementation 500 of a memory cell structure 202 described herein. FIG. 5A illustrates a perspective view of the example implementation 500 of the memory cell structure 202, and FIG. 5B illustrates a cross-section view of the example implementation 500 of the memory cell structure 202 along the line A-A in FIG. 5A.

As shown in FIGS. 5A and 5B, the example implementation 500 of the memory cell structure 202 includes a similar arrangement of structures and layers as the example implementation 300 of the memory cell structure 202 illustrated in FIGS. 2A-2C and 3A-3D. However, in the example implementation 500 of the memory cell structure 202, the source/drain interconnect 218 is omitted from the memory cell structure 202. Instead, the source/drain region 206 fully extends between the channel layer 212 (that is under the bottom surface of the gate electrode 214) and the top surface of the storage structure 204 such that the source/drain region 206 is in direction physical contact with the storage structure 204.

The inclusion of the source/drain interconnect 218 in the example implementation 300 of the memory cell structure 202 may enable the profile of the memory cell structure 202 to be more easily controlled during manufacturing of the memory cell structure 202. However, the omission of the source/drain interconnect 218 in the example implementation 500 of the memory cell structure 202 may enable the memory cell structure 202 to be formed using fewer photolithography operations and associated photomasks.

As further shown in FIGS. 5A and 5B, the source/drain region 206 may be tapered between the top surface of the source/drain region 206 and the bottom surface of the source/drain region 206. Accordingly, the source/drain region 206 may have a greater top surface cross-sectional width (indicated in FIG. 5B as dimension D4) than a bottom surface cross-sectional width (indicated in FIG. 5B as dimension D5). The cross-sectional width of the source/drain region 206 may decrease from the top surface to the bottom surface of the source/drain region 206 as result of the taper. The taper of the source/drain region 206 may result from an etch rate being greater at the top of a recess in which the source/drain region 206 is formed than an etch rate at the bottom of the recess in which the source/drain region 206 is formed.

As indicated above, FIGS. 5A and 5B are provided as an example. Other examples may differ from what is described with regard to FIGS. 5A and 5B.

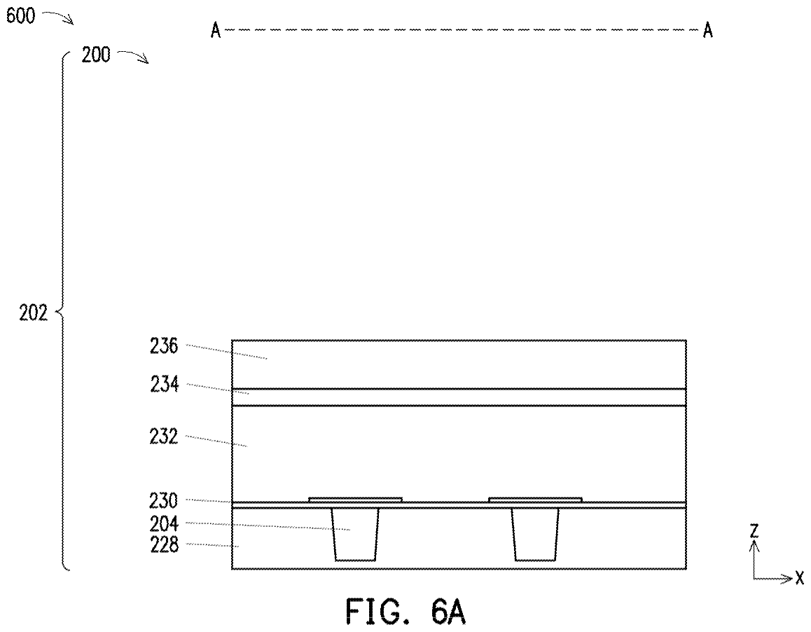

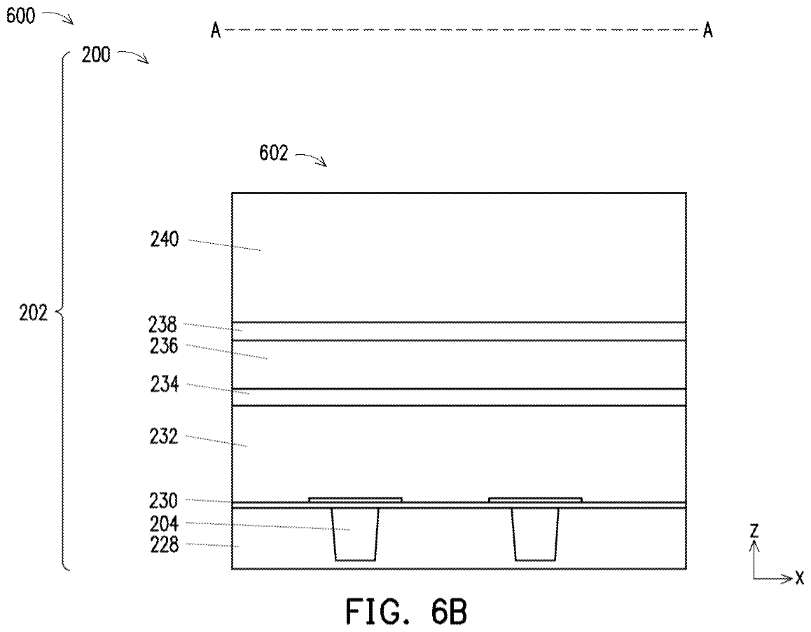

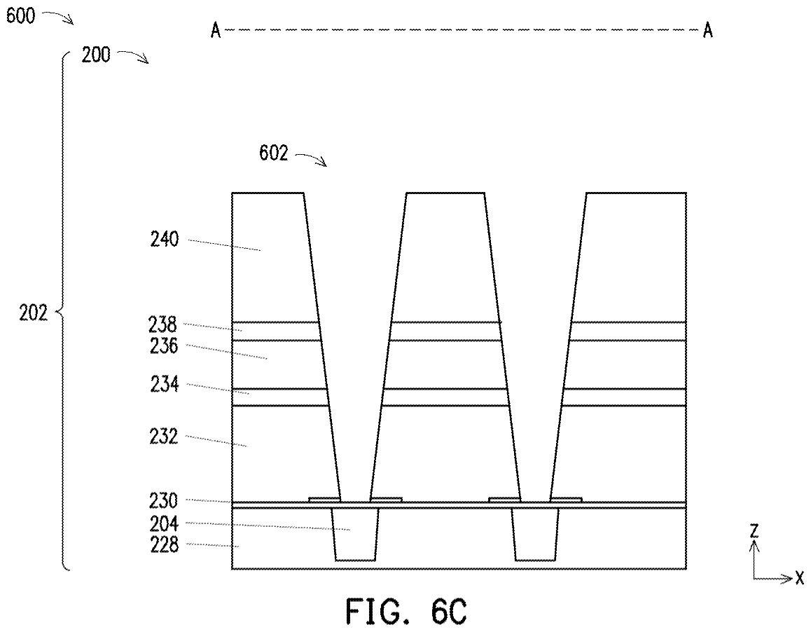

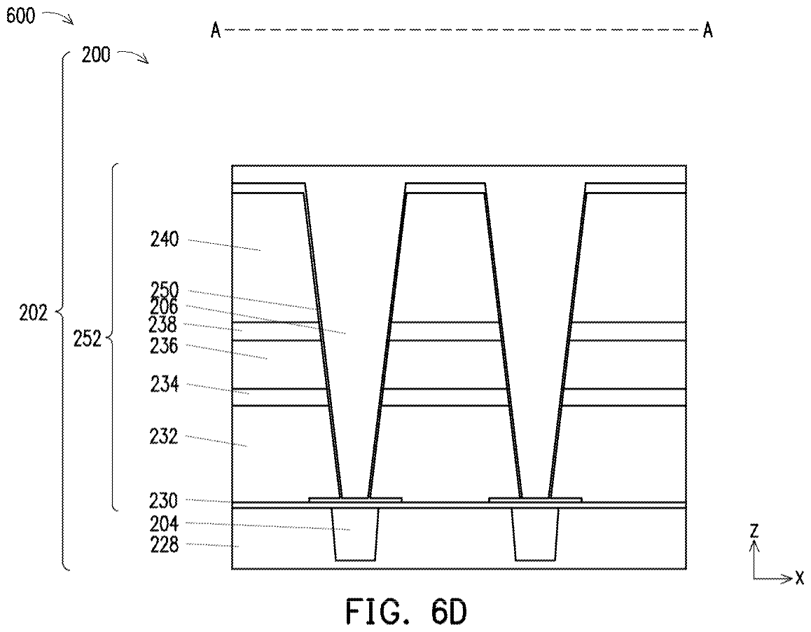

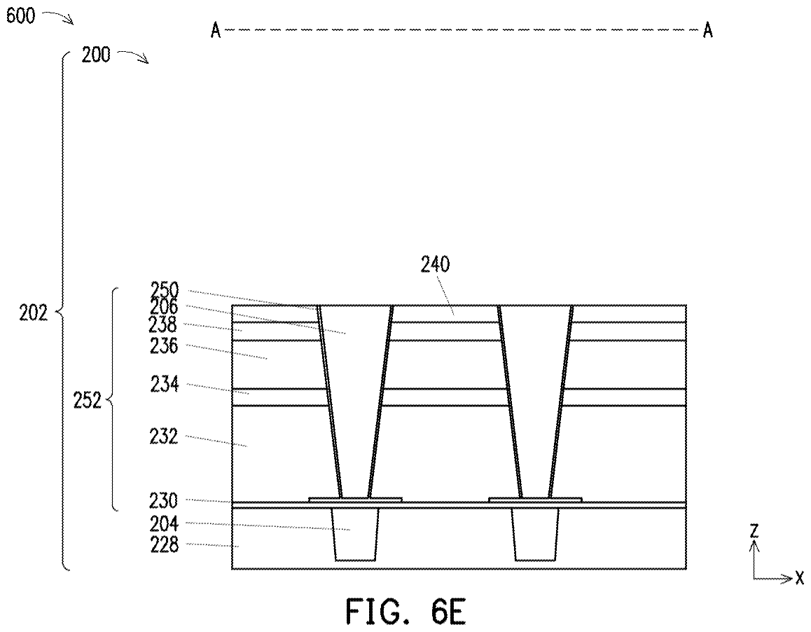

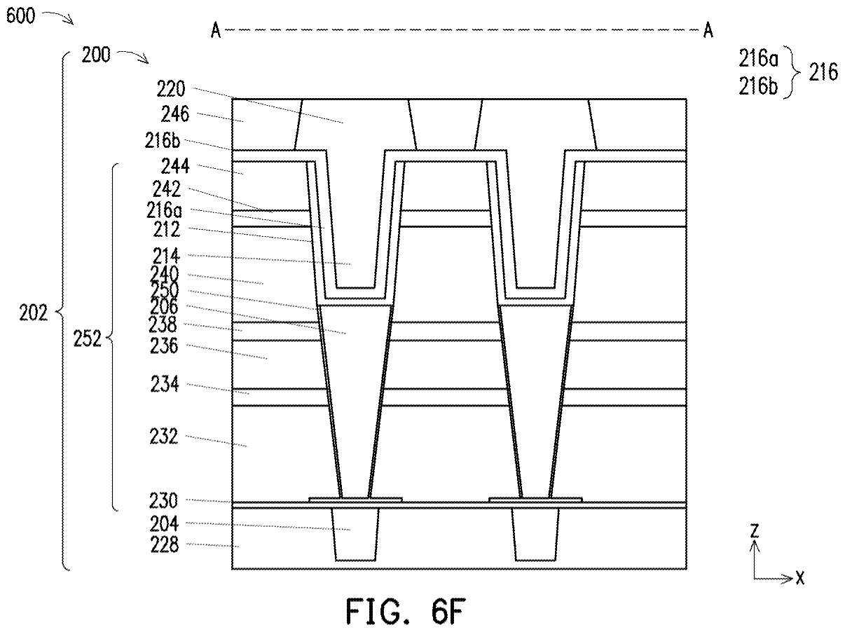

FIGS. 6A-6F are diagrams of an example implementation 600 of forming a memory cell structure 202 described herein. In particular, the example implementation 600 includes an example of forming the example implementation 500 of the memory cell structure 202 illustrated in FIGS. 5A and 5B. In some implementations, one or more of the semiconductor processing operations described in connection with FIGS. 6A-6F may be performed using one or more of the semiconductor processing tools 102-112 described herein. In some implementations, one or more of the semiconductor processing operations described in connection with FIGS. 6A-6F may be performed using another semiconductor processing tool. Some of FIGS. 6A-6F are illustrated from the cross-section view along the line-A-A in FIG. 2A, and some of FIGS. 6A-6F are illustrated from the cross-section view along the line-B-B in FIG. 2A.

Turning to FIG. 6A, similar semiconductor processing operations as described in connection with FIGS. 4A-4D may be performed to form the storage structure 204, the bit line conductive structure 222 (not shown), the dielectric layer 228, the ESL, the dielectric layer 232, the ESL 234, and the dielectric layer 236, and the liner layer(s) 254 (not shown).

As shown in FIG. 6B, the ESL 238 may be formed over and/or on the dielectric layer 236, and the dielectric layer 240 may be formed over and/or on the ESL 238 in a similar manner as described in connection with FIG. 4G. However, forming the source/drain interconnect 218 is omitted prior to forming the ESL 238 and the dielectric layer 236.

As shown in FIG. 6C, a recess 602 is formed through the dielectric layer 240, through the ESL 238, through the dielectric layer 236, through the ESL 234, and/or through the dielectric layer 232 to the storage structure 204. The top surface of the storage structure 204 is exposed through the recess 602. The recess 602 may be formed in the z-direction from the top surface of the dielectric layer 240 to the top surface of the storage structure 204.

In some implementations, a pattern in a photoresist layer is used to etch the dielectric layer 240, the ESL 238, the dielectric layer 236, the ESL 234, and/or the dielectric layer 232 to form the recess 602. In these implementations, a deposition tool 102 may be used to form the photoresist layer on the dielectric layer 240. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 240, the ESL 238, the dielectric layer 236, the ESL 234, and/or the dielectric layer 232 based on the pattern to form the recess 602. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 602 based on a pattern.

As shown in FIG. 6D, the liner layer(s) 250 are formed on sidewalls and on a bottom surface of the recess 602. The liner layer(s) 250 may be conformally deposited such that the liner layer(s) 250 conform to a profile of the recess 602. The liner layer(s) 250 may also be formed on the top surface of the dielectric layer 240. A deposition tool 102 may be used to deposit the liner layer(s) 250 using a PVD technique, an ALD technique, a CVD technique, another type of deposition technique described in connection with FIG. 1, and/or another suitable deposition technique.

As further shown in FIG. 6D, the recess 602 may be filled with the source/drain region 206 on the liner layer(s) 250. In this way, the source/drain region 206 is formed on the storage structure 204 instead of being formed on the source/drain interconnect 218. A deposition tool 102 and/or a plating tool 112 may be used to deposit the source/drain region 206 using a CVD technique, a PVD technique, an ALD technique, an electroplating technique, another deposition technique described above in connection with FIG. 1, and/or another suitable deposition technique. In some implementations, a seed layer is first deposited on the liner layer(s) 250, and the source/drain region 206 is deposited on the seed layer.

As shown in FIG. 6E, a planarization tool 110 may be used to planarize the semiconductor device 200 after the liner layer(s) 250 and the source/drain region 206 are deposited. The planarization tool 110 may be performed to remove material of the liner layer(s) 250 and material of the source/drain region 206 from the top surface of the dielectric layer 240.

As shown in FIG. 6F, similar semiconductor processing operations as described in connection with FIGS. 4K-4X may be performed to form the source/drain regions 208 and 210 (not shown), the channel layer 212, the gate electrode 214, the gate dielectric layer 216, the word line conductive structure 220, the source/drain interconnects 224 and 226 (not shown), the additional material of the dielectric layer 240, the ESL 242, the dielectric layer 244, the dielectric layer 246, and the liner layer(s) 256, 258, 260, and 262 (not shown).

As indicated above, FIGS. 6A-6F are provided as an example. Other examples may differ from what is described with regard to FIGS. 6A-6F.

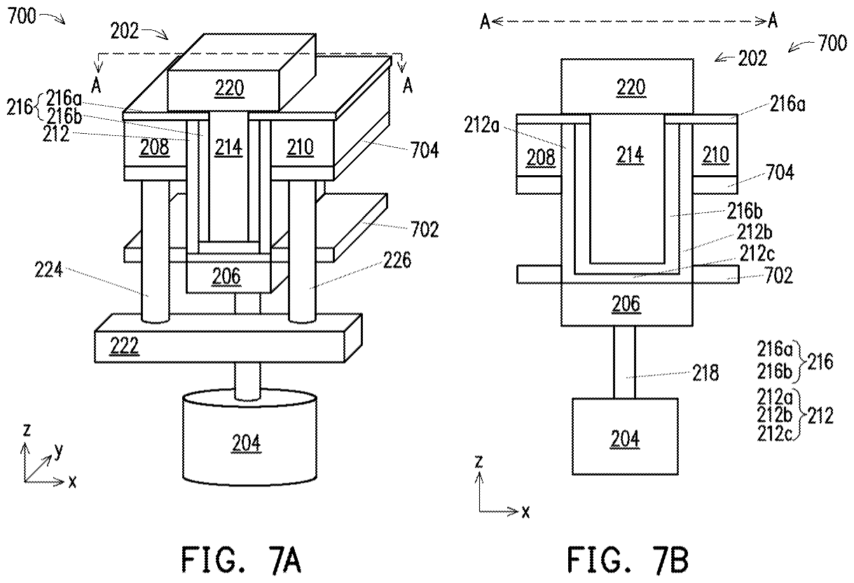

FIGS. 7A and 7B are diagrams of an example implementation 700 of a memory cell structure 202 described herein. FIG. 7A illustrates a perspective view of the example implementation 700 of the memory cell structure 202, and FIG. 7B illustrates a cross-section view of the example implementation 700 of the memory cell structure 202 along the line A-A in FIG. 7A.

As shown in FIGS. 7A and 7B, the example implementation 700 of the memory cell structure 202 includes a similar arrangement of structures and layers as the example implementation 300 of the memory cell structure 202 illustrated in FIGS. 2A-2C and 3A-3D. However, in the example implementation 700 of the memory cell structure 202, one or more diffusion barrier layers are included around the memory cell structure 202. For example, a diffusion barrier layer 702 may be located above the source/drain region 206 and around the bottom segment 212c of the channel layer 212 (and thus, around the bottom of the gate electrode 214). As another example, a diffusion barrier layer 704 may be located under the source/drain regions 208 and/or 210, and around a portion of the sidewall segments 212a and 212b of the channel layer 212 (and thus, around the middle of the gate electrode 214).

As indicated above, the channel layer 212 may include one or more metal-oxide semiconductor materials such as IGZO and/or ITO, among other examples. These types of materials may be susceptible to contamination by diffusion of elements and/or molecules such as oxygen (O), nitrogen (N), hydrogen (H), and/or water (H₂O), among other examples. These contaminants can generate vacancy defects in the metal-oxide semiconductor material(s) of the channel layer 212, resulting in increased leakage current in the memory cell structure 202. The diffusion barrier layers 702 and 704 may be included around the channel layer 212 of the memory cell structure 202 to prevent or reduce the likelihood of these and other contaminants from diffusing into the channel layer 212 from below the diffusion barrier layer 702 and from above the diffusion barrier layer 704.

In some implementations, additional diffusion barrier layers and/or different placement of the diffusion barrier layers 702 and/or 704 may be arranged in the semiconductor device 200. For example, the diffusion barrier layer 702 (and/or another diffusion barrier layer) may be located under the storage structure 204. As another example, the diffusion barrier layer 704 (and/or another diffusion barrier layer) may be located above the word line conductive structure 220.

The diffusion barrier layers 702 and/or 704 may each include one or more hydrogen-blocking materials, one or more nitrogen-blocking materials, and/or one or more oxygen-blocking materials, among other examples. Examples of such materials include aluminum oxide (AlₓO_{y} such as Al₂O₃), silicon oxycarbide (SiOC), chromium oxide (CrₓO_{y} such as Cr₂O₃), another oxide-containing material, and/or another material, among other examples.

As indicated above, FIGS. 7A and 7B are provided as an example. Other examples may differ from what is described with regard to FIGS. 7A and 7B.

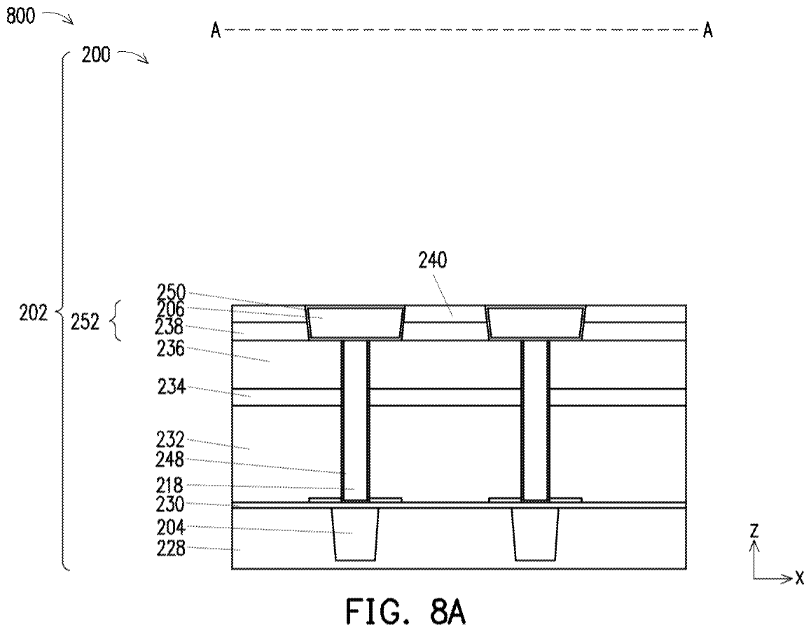

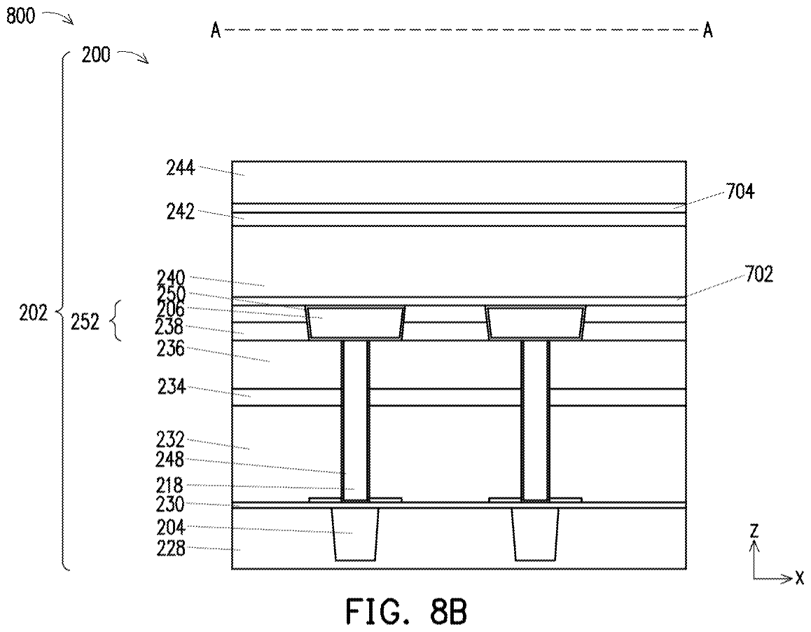

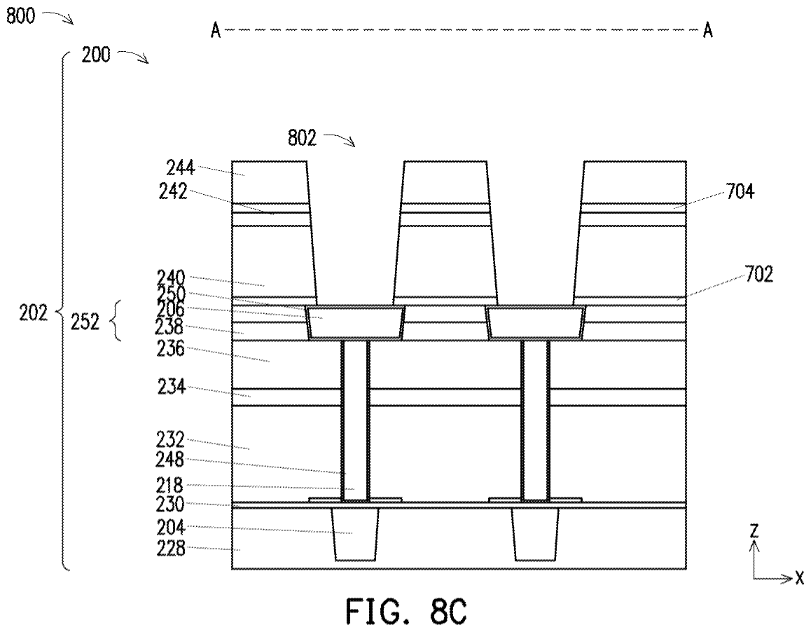

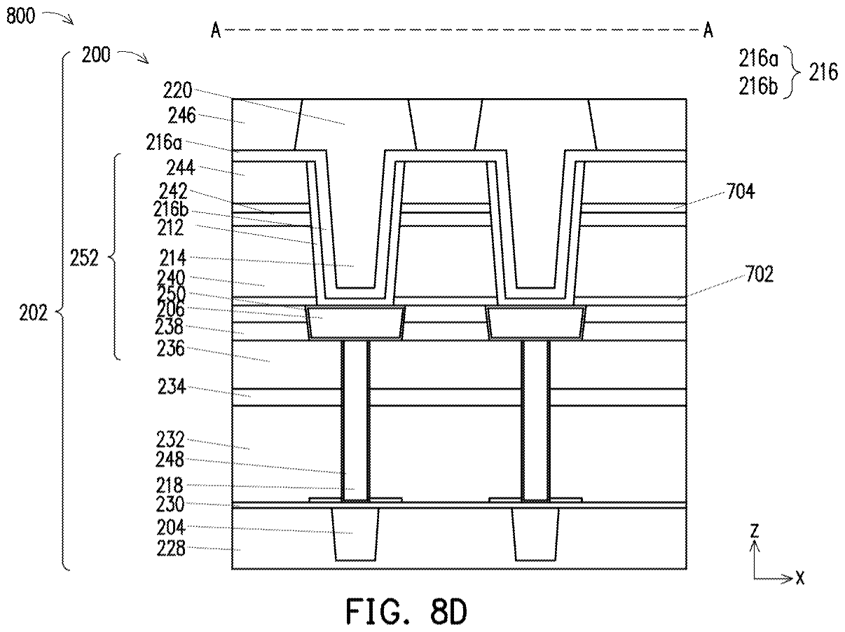

FIGS. 8A-8D are diagrams of an example implementation 800 of forming a memory cell structure 202 described herein. In particular, the example implementation 800 includes an example of forming the example implementation 700 of the memory cell structure 202 illustrated in FIGS. 7A and 7B. In some implementations, one or more of the semiconductor processing operations described in connection with FIGS. 8A-8D may be performed using one or more of the semiconductor processing tools 102-112 described herein. In some implementations, one or more of the semiconductor processing operations described in connection with FIGS. 8A-8D may be performed using another semiconductor processing tool. Some of FIGS. 8A-8D are illustrated from the cross-section view along the line-A-A in FIG. 2A, and some of FIGS. 8A-8D are illustrated from the cross-section view along the line-B-B in FIG. 2A.

Turning to FIG. 8A, similar semiconductor processing operations as described in connection with FIGS. 4A-4I may be performed to form the storage structure 204, the source/drain region 206, the source/drain interconnect 218, the bit line conductive structure 222 (not shown), the dielectric layer 228, the ESL, the dielectric layer 232, the ESL 234, the dielectric layer 236, the ESL 238, the dielectric layer 240, the liner layer(s) 248, the liner layer(s) 250, and the liner layer(s) 254 (not shown).

As shown in FIG. 8B, an additional portion of the dielectric layer 240 is formed over and/or on the source/drain region 206, the ESL 242 is formed over and/or on the dielectric layer 240, and the dielectric layer 244 is formed over and/or on the ESL 242 in a similar manner as described in connection with FIG. 4J. However, the diffusion barrier layers 702 and 704 are additionally formed during formation of the additional portion of the dielectric layer 240, the ESL 242, and the dielectric layer 244. For example, the diffusion barrier layer 702 may be formed over and/or on the dielectric layer 240 and/or over and/or on the source/drain region 206. The additional portion of the dielectric layer 240 may be formed over and/or on the diffusion barrier layer 702. The ESL 242 may be formed over and/or on the additional portion of the dielectric layer 240. The diffusion barrier layer 704 may be formed over and/or on the ESL 242. The dielectric layer 244 may be formed over and/or on the diffusion barrier layer 704.

A deposition tool 102 may be used to deposit the additional portion of the dielectric layer 240, the ESL 242, the dielectric layer 244, the diffusion barrier layer 702, and/or the diffusion barrier layer 704 using a PVD technique, an ALD technique, a CVD technique, another type of deposition technique described in connection with FIG. 1, and/or another suitable deposition technique. In some implementations, a planarization tool 110 is used to planarize the additional portion of the dielectric layer 240, the ESL 242, the dielectric layer 244, the diffusion barrier layer 702, and/or the diffusion barrier layer 704 after the additional portion of the dielectric layer 240, the ESL 242, the dielectric layer 244, the diffusion barrier layer 702, and/or the diffusion barrier layer 704 are formed.

The conductive layer 404 (not shown), the source/drain interconnects 224 and 226 (not shown), and the liner layer(s) 256, 258, and 406 (not shown) may be formed in a similar manner as described in connection with FIG. 4K after formation of the additional portion of the dielectric layer 240, the ESL 242, the dielectric layer 244, the diffusion barrier layer 702, and/or the diffusion barrier layer 704.

As shown in FIG. 8C, a recess 802 is formed through the dielectric layer 244, through the diffusion barrier layer 704, through the ESL 242, through the additional portion of the dielectric layer 240, and through the diffusion barrier layer 702 to the source/drain region 206. Forming the recess 802 includes removing of portions of the conductive layer 404, which results in formation of the source/drain regions 208 and 210 (not shown) and the associated liner layer(s) 260 and/or 262, respectively. The top surface of the source/drain region 206 is exposed through the recess 802. The recess 802 may be formed in the z-direction from the top surface of the dielectric layer 244 to the top surface of the source/drain region 206.

In some implementations, a pattern in a photoresist layer is used to etch the dielectric layer 244, the diffusion barrier layer 704, the ESL 242, the additional portion of the dielectric layer 240, the diffusion barrier layer 702, and the conductive layer 404 to form the recess 802. In these implementations, a deposition tool 102 may be used to form the photoresist layer on the dielectric layer 244. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 244, the diffusion barrier layer 704, the ESL 242, the additional portion of the dielectric layer 240, the diffusion barrier layer 702, and the conductive layer 404 based on the pattern to form the recess 802. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 802 based on a pattern.

As shown in FIG. 8D, similar semiconductor processing operations as described in connection with FIGS. 4N-4X may be performed to form the channel layer 212, the gate electrode 214, and the gate dielectric layer 216 in the recess 802, and to form the word line conductive structure 220 and the dielectric layer 246.

As indicated above, FIGS. 8A-8D are provided as an example. Other examples may differ from what is described with regard to FIGS. 8A-8D.

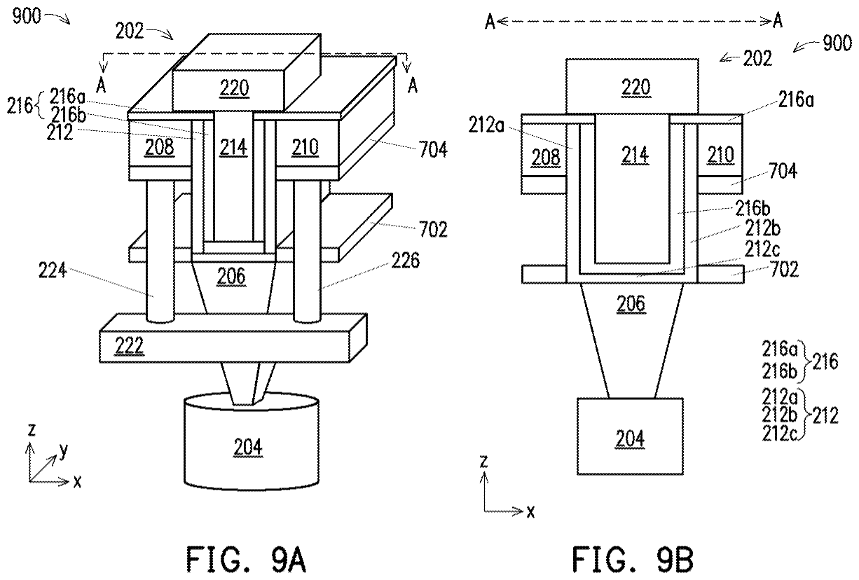

FIGS. 9A and 9B are diagrams of an example implementation 900 of a memory cell structure 202 described herein. FIG. 9A illustrates a perspective view of the example implementation 900 of the memory cell structure 202, and FIG. 9B illustrates a cross-section view of the example implementation 900 of the memory cell structure 202 along the line A-A in FIG. 9A.

As shown in FIGS. 9A and 9B, the example implementation 900 of the memory cell structure 202 includes a similar arrangement of structures and layers as the example implementation 500 of the memory cell structure 202 illustrated in FIGS. 5A and 5B. In addition to the tapered source/drain region 206 and omission of the source/drain interconnect 218, the diffusion barrier layers 702 and/or 704 are included around the channel layer 212 in the example implementation 900 of the memory cell structure 202. This enables one or more metal-oxide semiconductor materials to be used for the channel layer 212 in combination with the tapered source/drain region 206.

As indicated above, FIGS. 9A and 9B are provided as an example. Other examples may differ from what is described with regard to FIGS. 9A and 9B.

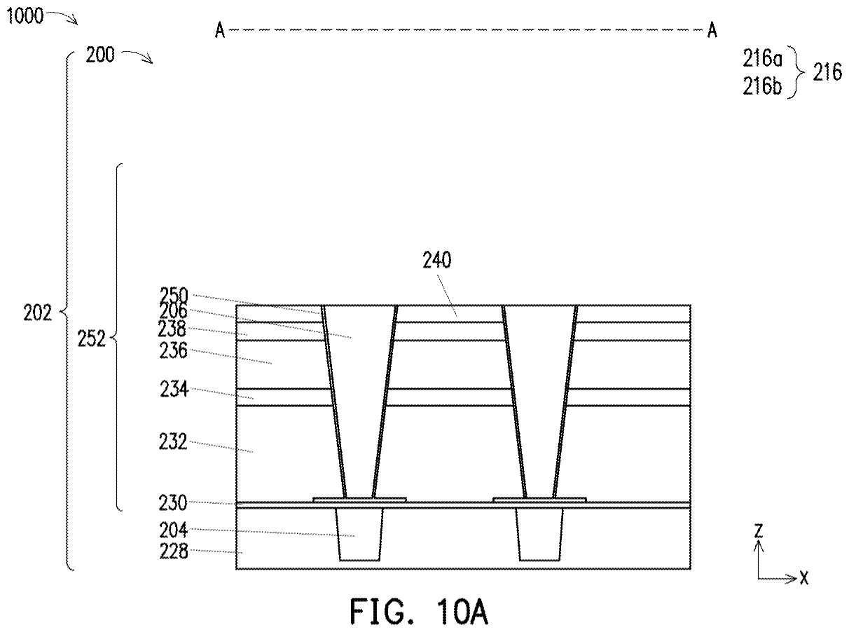

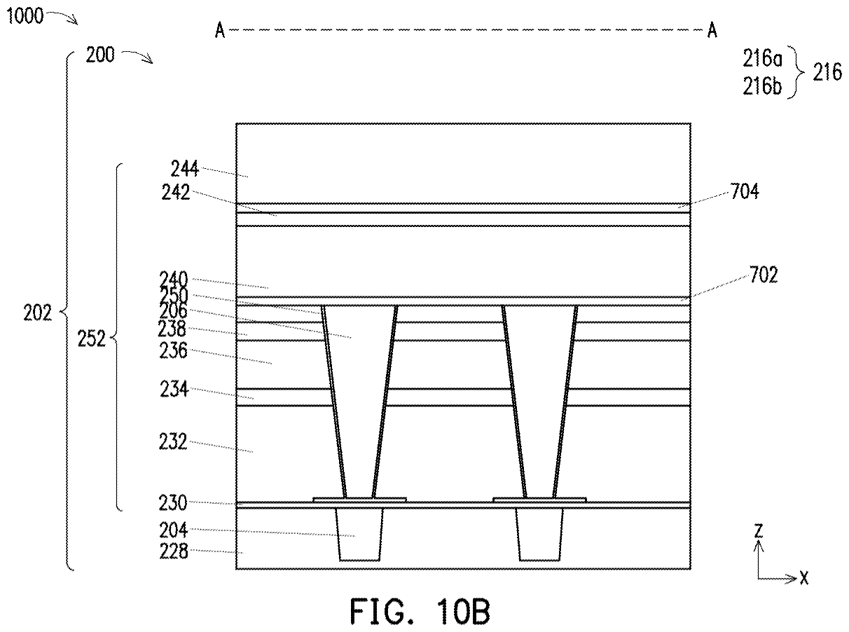

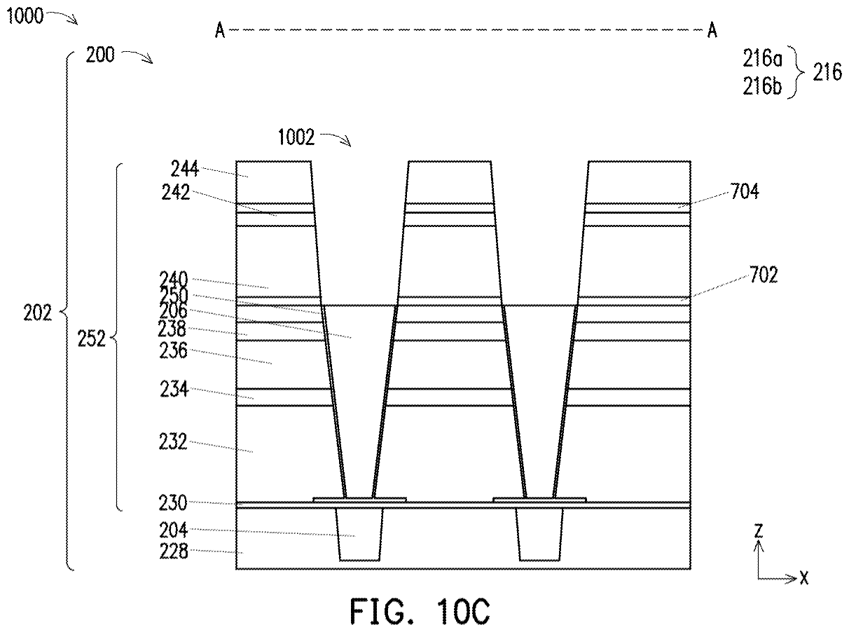

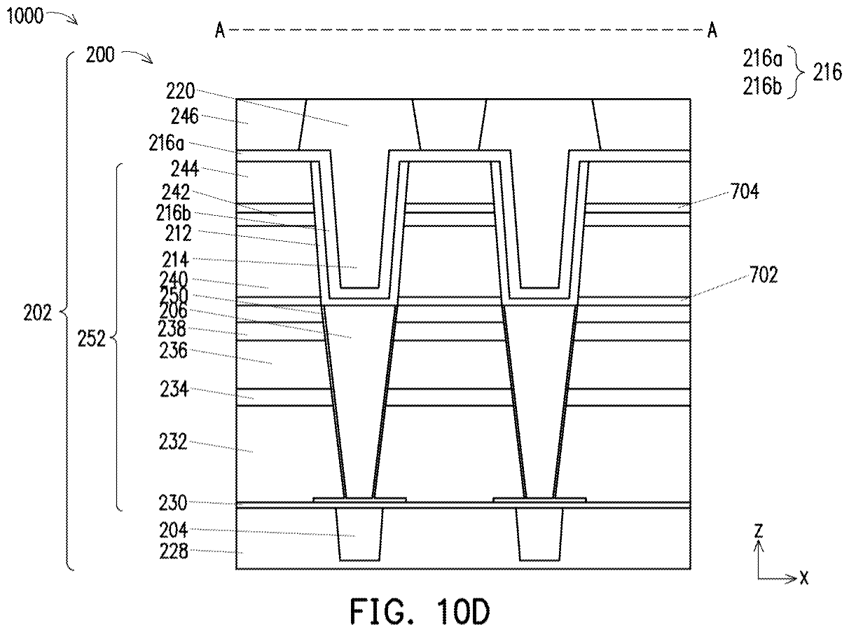

FIGS. 10A-10D are diagrams of an example implementation 1000 of forming a memory cell structure 202 described herein. In particular, the example implementation 1000 includes an example of forming the example implementation 900 of the memory cell structure 202 illustrated in FIGS. 9A and 9B. In some implementations, one or more of the semiconductor processing operations described in connection with FIGS. 10A-10D may be performed using one or more of the semiconductor processing tools 102-112 described herein. In some implementations, one or more of the semiconductor processing operations described in connection with FIGS. 10A-10D may be performed using another semiconductor processing tool. Some of FIGS. 10A-10D are illustrated from the cross-section view along the line-A-A in FIG. 2A, and some of FIGS. 10A-10D are illustrated from the cross-section view along the line-B-B in FIG. 2A.

Turning to FIG. 10A, similar semiconductor processing operations as described in connection with FIGS. 4A-4D and 6A-6E may be performed to form the storage structure 204, the source/drain region 206 on the storage structure 204 (where the source/drain interconnect 218 is omitted), the bit line conductive structure 222 (not shown), the dielectric layer 228, the ESL 230, the dielectric layer 232, the ESL 234, the dielectric layer 236, the ESL 238, the dielectric layer 240, the liner layer(s) 250, and the liner layer(s) 254 (not shown).

As shown in FIG. 10B, an additional portion of the dielectric layer 240 is formed over and/or on the source/drain region 206, the ESL 242 is formed over and/or on the dielectric layer 240, and the dielectric layer 244 is formed over and/or on the ESL 242 in a similar manner as described in connection with FIG. 4J. However, the diffusion barrier layers 702 and 704 are additionally formed during formation of the additional portion of the dielectric layer 240, the ESL 242, and the dielectric layer 244. For example, the diffusion barrier layer 702 may be formed over and/or on the dielectric layer 240 and/or over and/or on the source/drain region 206. The additional portion of the dielectric layer 240 may be formed over and/or on the diffusion barrier layer 702. The ESL 242 may be formed over and/or on the additional portion of the dielectric layer 240. The diffusion barrier layer 704 may be formed over and/or on the ESL 242. The dielectric layer 244 may be formed over and/or on the diffusion barrier layer 704.

A deposition tool 102 may be used to deposit the additional portion of the dielectric layer 240, the ESL 242, the dielectric layer 244, the diffusion barrier layer 702, and/or the diffusion barrier layer 704 using a PVD technique, an ALD technique, a CVD technique, another type of deposition technique described in connection with FIG. 1, and/or another suitable deposition technique. In some implementations, a planarization tool 110 is used to planarize the additional portion of the dielectric layer 240, the ESL 242, the dielectric layer 244, the diffusion barrier layer 702, and/or the diffusion barrier layer 704 after the additional portion of the dielectric layer 240, the ESL 242, the dielectric layer 244, the diffusion barrier layer 702, and/or the diffusion barrier layer 704 are formed.

The conductive layer 404 (not shown), the source/drain interconnects 224 and 226 (not shown), and the liner layer(s) 256, 258, and 406 (not shown) may be formed in a similar manner as described in connection with FIG. 4K after formation of the additional portion of the dielectric layer 240, the ESL 242, the dielectric layer 244, the diffusion barrier layer 702, and/or the diffusion barrier layer 704.

As shown in FIG. 10C, a recess 1002 is formed through the dielectric layer 244, through the diffusion barrier layer 704, through the ESL 242, through the additional portion of the dielectric layer 240, and through the diffusion barrier layer 702 to the source/drain region 206. Forming the recess 1002 includes removing of portions of the conductive layer 404, which results in formation of the source/drain regions 208 and 210 (not shown) and the associated liner layer(s) 260 and/or 262, respectively. The top surface of the source/drain region 206 is exposed through the recess 1002. The recess 1002 may be formed in the z-direction from the top surface of the dielectric layer 244 to the top surface of the source/drain region 206.

In some implementations, a pattern in a photoresist layer is used to etch the dielectric layer 244, the diffusion barrier layer 704, the ESL 242, the additional portion of the dielectric layer 240, the diffusion barrier layer 702, and the conductive layer 404 to form the recess 1002. In these implementations, a deposition tool 102 may be used to form the photoresist layer on the dielectric layer 244. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 244, the diffusion barrier layer 704, the ESL 242, the additional portion of the dielectric layer 240, the diffusion barrier layer 702, and the conductive layer 404 based on the pattern to form the recess 1002. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 1002 based on a pattern.

As shown in FIG. 10D, similar semiconductor processing operations as described in connection with FIGS. 4N-4U may be performed to form the channel layer 212, the gate electrode 214, and the gate dielectric layer 216 in the recess 1002, and to form the word line conductive structure 220 and the dielectric layer 246.

As indicated above, FIGS. 10A-10D are provided as an example. Other examples may differ from what is described with regard to FIGS. 10A-10D.

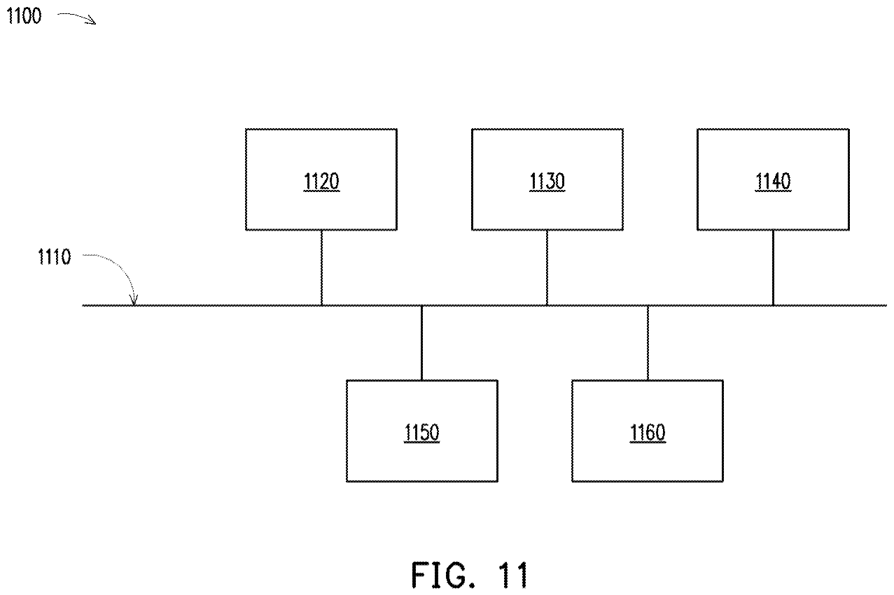

FIG. 11 is a diagram of example components of a device 1100 described herein. In some implementations, one or more of the semiconductor processing tools 102-112 and/or the wafer/die transport tool 114 may include one or more devices 1100 and/or one or more components of the device 1100. As shown in FIG. 11, the device 1100 may include a bus 1110, a processor 1120, a memory 1130, an input component 1140, an output component 1150, and/or a communication component 1160.

The bus 1110 may include one or more components that enable wired and/or wireless communication among the components of the device 1100. The bus 1110 may couple together two or more components of FIG. 11, such as via operative coupling, communicative coupling, electronic coupling, and/or electric coupling. For example, the bus 1110 may include an electrical connection (e.g., a wire, a trace, and/or a lead) and/or a wireless bus. The processor 1120 may include a central processing unit, a graphics processing unit, a microprocessor, a controller, a microcontroller, a digital signal processor, a field-programmable gate array, an application-specific integrated circuit, and/or another type of processing component. The processor 1120 may be implemented in hardware, firmware, or a combination of hardware and software. In some implementations, the processor 1120 may include one or more processors capable of being programmed to perform one or more operations or processes described elsewhere herein.

The memory 1130 may include volatile and/or nonvolatile memory. For example, the memory 1130 may include random access memory (RAM), read only memory (ROM), a hard disk drive, and/or another type of memory (e.g., a flash memory, a magnetic memory, and/or an optical memory). The memory 1130 may include internal memory (e.g., RAM, ROM, or a hard disk drive) and/or removable memory (e.g., removable via a universal serial bus connection). The memory 1130 may be a non-transitory computer-readable medium. The memory 1130 may store information, one or more instructions, and/or software (e.g., one or more software applications) related to the operation of the device 1100. In some implementations, the memory 1130 may include one or more memories that are coupled (e.g., communicatively coupled) to one or more processors (e.g., processor 1120), such as via the bus 1110. Communicative coupling between a processor 1120 and a memory 1130 may enable the processor 1120 to read and/or process information stored in the memory 1130 and/or to store information in the memory 1130.

The input component 1140 may enable the device 1100 to receive input, such as user input and/or sensed input. For example, the input component 1140 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1150 may enable the device 1100 to provide output, such as via a display, a speaker, and/or a light-emitting diode. The communication component 1160 may enable the device 1100 to communicate with other devices via a wired connection and/or a wireless connection. For example, the communication component 1160 may include a receiver, a transmitter, a transceiver, a modem, a network interface card, and/or an antenna.

The device 1100 may perform one or more operations or processes described herein. For example, a non-transitory computer-readable medium (e.g., memory 1130) may store a set of instructions (e.g., one or more instructions or code) for execution by the processor 1120. The processor 1120 may execute the set of instructions to perform one or more operations or processes described herein. In some implementations, execution of the set of instructions, by one or more processors 1120, causes the one or more processors 1120 and/or the device 1100 to perform one or more operations or processes described herein. In some implementations, hardwired circuitry may be used instead of or in combination with the instructions to perform one or more operations or processes described herein. Additionally, or alternatively, the processor 1120 may be configured to perform one or more operations or processes described herein. Thus, implementations described herein are not limited to any specific combination of hardware circuitry and software.

The number and arrangement of components shown in FIG. 11 are provided as an example. The device 1100 may include additional components, fewer components, different components, or differently arranged components than those shown in FIG. 11. Additionally, or alternatively, a set of components (e.g., one or more components) of the device 1100 may perform one or more functions described as being performed by another set of components of the device 1100.

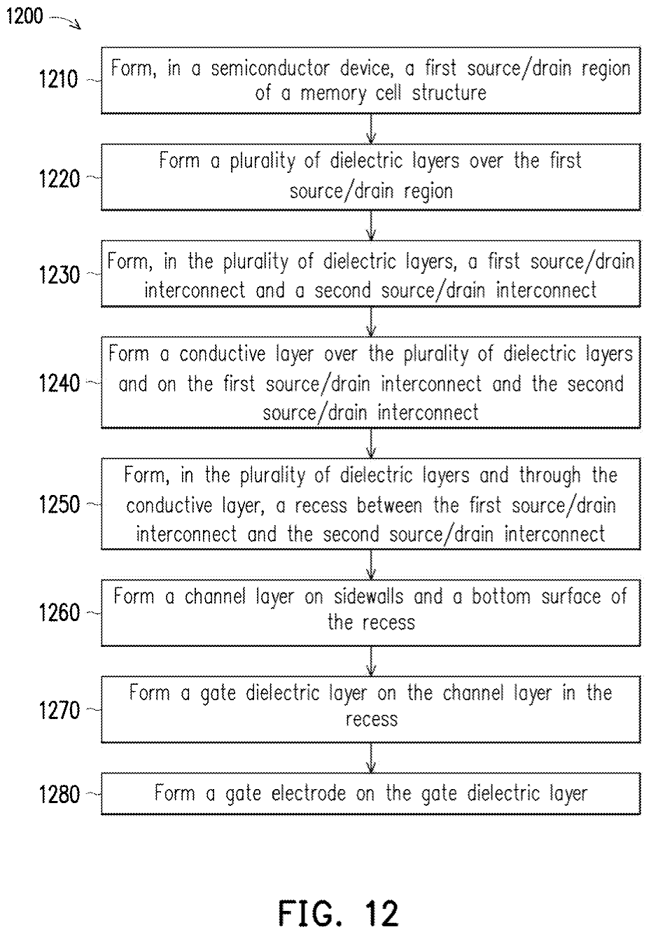

FIG. 12 is a flowchart of an example process 1200 associated with forming a memory cell structure described herein. In some implementations, one or more process blocks of FIG. 12 are performed using one or more semiconductor processing tools (e.g., one or more of the semiconductor processing tools 102-112). Additionally, or alternatively, one or more process blocks of FIG. 12 may be performed using one or more components of device 1100, such as processor 1120, memory 1130, input component 1140, output component 1150, and/or communication component 1160.

As shown in FIG. 12, process 1200 may include forming, in a semiconductor device, a first source/drain region of a memory cell structure (block 1210). For example, one or more of the semiconductor processing tools 102-112 may be used to form, in a semiconductor device 200, a first source/drain region 206 of a memory cell structure 202, as described herein.

As further shown in FIG. 12, process 1200 may include forming a plurality of dielectric layers over the first source/drain region (block 1220). For example, one or more of the semiconductor processing tools 102-112 may be used to form a plurality of dielectric layers (e.g., the dielectric layer 240, the dielectric layer 244, the ESL 242, the diffusion barrier layer 702, the diffusion barrier layer 704) over the first source/drain region 206, as described herein.

As further shown in FIG. 12, process 1200 may include forming, in the plurality of dielectric layers, a first source/drain interconnect and a second source/drain interconnect (block 1230). For example, one or more of the semiconductor processing tools 102-112 may be used to form, in the plurality of dielectric layers, a first source/drain interconnect 224 and a second source/drain interconnect 226, as described herein.

As further shown in FIG. 12, process 1200 may include forming a conductive layer over the plurality of dielectric layers and on the first source/drain interconnect and the second source/drain interconnect (block 1240). For example, one or more of the semiconductor processing tools 102-112 may be used to form a conductive layer 404 over the plurality of dielectric layers and on the first source/drain interconnect 224 and the second source/drain interconnect 226, as described herein.

As further shown in FIG. 12, process 1200 may include forming, in the plurality of dielectric layers and through the conductive layer, a recess between the first source/drain interconnect and the second source/drain interconnect (block 1250). For example, one or more of the semiconductor processing tools 102-112 may be used to form, in the plurality of dielectric layers and through the conductive layer 404, a recess 408 between the first source/drain interconnect 224 and the second source/drain interconnect 226, as described herein. In some implementations, forming the recess 408 through the conductive layer 404 results in formation of a second source/drain region 208 above the first source/drain interconnect 224 and a third source/drain region 210 above the second source/drain interconnect 226.

As further shown in FIG. 12, process 1200 may include forming a channel layer (212) on sidewalls and a bottom surface of the recess (block 1260). For example, one or more of the semiconductor processing tools 102-112 may be used to form a channel layer 212 on sidewalls and a bottom surface of the recess 408, as described herein.

As further shown in FIG. 12, process 1200 may include forming a gate dielectric layer on the channel layer in the recess (block 1270). For example, one or more of the semiconductor processing tools 102-112 may be used to form a gate dielectric layer 216 on the channel layer 212 in the recess 408, as described herein.

As further shown in FIG. 12, process 1200 may include forming a gate electrode on the gate dielectric layer (block 1280). For example, one or more of the semiconductor processing tools 102-112 may be used to form a gate electrode 214 on the gate dielectric layer 216, as described herein.

Process 1200 may include additional implementations, such as any single implementation or any combination of implementations described below and/or in connection with one or more other processes described elsewhere herein.

In a first implementation, forming the gate dielectric layer 216 includes forming a first portion (e.g., a portion 216a) of the gate dielectric layer 216 on the channel layer 212 in the recess 408, and forming a second portion (e.g., a portion 216c) of the gate dielectric layer 216 on a top surface of a dielectric layer 244 of the plurality of dielectric layers, and process 1200 includes filling the recess 408 with a sacrificial layer 410 on the gate dielectric layer 216 prior to forming the gate electrode 214, removing the second portion of the gate dielectric layer 216 after filling the recess 408 with the sacrificial layer 410, removing the sacrificial layer 410 from the recess 408 after removing the second portion of the gate dielectric layer 216, depositing additional material of the first portion of the gate dielectric layer 216 in the recess 408, where depositing the additional material of the first portion of the gate dielectric layer 216 results in formation of a third portion (e.g., a portion 216b) of the gate dielectric layer 216 on the dielectric layer 244, and forming the gate electrode 214 on the first portion of the gate dielectric layer 216 in the recess 408 after depositing the additional material of the first portion of the gate dielectric layer 216.

In a second implementation, alone or in combination with the first implementation, process 1200 includes forming a word line conductive structure 220 on the gate electrode 214 and on the third portion of the gate dielectric layer 216.

In a third implementation, alone or in combination with one or more of the first and second implementations, forming the word line conductive structure 220 includes depositing a conductive layer 412 on the third portion of the gate dielectric layer 216 and on the gate electrode 214, and removing portions of the conductive layer 412, where remaining portions of the conductive layer 412 correspond to the word line conductive structure 220.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

In this way, a semiconductor device includes a memory cell structure that includes a transistor structure and a storage structure. A gate electrode of the transistor structure extends in a direction that is approximately perpendicular to a surface of a substrate of the semiconductor device, which enables the gate length to be increased with minimal to no increase in horizontal or lateral size of the memory cell structure. A channel layer may be a U-shaped layer in that the channel layer is included on at least two of the sidewalls and on the bottom surface of the gate electrode. This increases the channel area of the transistor structure, which enables a low current leakage to be achieved for the memory cell structure, and enables a high lateral density of memory cell structures to be achieved in the semiconductor device. The low current leakage of the memory cell structure enables data stored in the storage structure of the memory cell structure to retain data for longer time durations between refreshes, which reduces the power consumption of the memory cell structure and increases the power efficiency of the memory cell structure.

As described in greater detail above, some implementations described herein provide a semiconductor device. The semiconductor device includes a plurality of backend dielectric layers. The semiconductor device includes a memory cell structure in the plurality of backend dielectric layers. The memory cell structure includes a storage structure and a transistor structure above the storage structure. The transistor structure includes a first source/drain region, a second source/drain region above the first source/drain region, a gate electrode, and a channel layer. The gate electrode extends between the first source/drain region and the second source/drain region. The channel layer extends between the first source/drain region and the second source/drain region. The channel layer is included on at least two sides of the gate electrode and under a bottom surface of the gate electrode.

As described in greater detail above, some implementations described herein provide a semiconductor device. The semiconductor device includes a plurality of backend dielectric layers. The semiconductor device includes a memory cell structure in the plurality of backend dielectric layers, and the memory cell structure includes a storage structure. The memory cell structure includes a first source/drain region. The memory cell structure includes a second source/drain region above the first source/drain region. The memory cell structure includes a gate electrode having an elongated shape in a direction that is approximately perpendicular with the plurality of backend dielectric layers. The first source/drain region is located under a bottom surface of the gate electrode. The second source drain region is located adjacent to opposing sidewalls of the gate electrode. The memory cell structure includes a channel layer that included on at least two sides of the gate electrode and under the bottom surface of the gate electrode. The first source/drain region is in contact with a bottom segment of the channel layer that is between a bottom surface of the gate electrode and the first source/drain region. The second source/drain region is in contact with a side segment of the channel layer that is between a sidewall of the gate electrode and the second source/drain region.

As described in greater detail above, some implementations described herein provide a method. The method includes forming, in a semiconductor device, a first source/drain region of a memory cell structure. The method includes forming a plurality of dielectric layers over the first source/drain region. The method includes forming, in the plurality of dielectric layers, a first source/drain interconnect and a second source/drain interconnect. The method includes forming a conductive layer over the plurality of dielectric layers and on the first source/drain interconnect and the second source/drain interconnect. The method includes forming, in the plurality of dielectric layers and through the conductive layer, a recess between the first source/drain interconnect and the second source/drain interconnect, where forming the recess through the conductive layer results in formation of a second source/drain region above the first source/drain interconnect. The method includes forming a channel layer on sidewalls and a bottom surface of the recess. The method includes forming a gate dielectric layer on the channel layer in the recess. The method includes forming a gate electrode on the gate dielectric layer.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of backend dielectric layers; and
a memory cell structure, in the plurality of backend dielectric layers, comprising:
a storage structure; and
a transistor structure, above the storage structure, comprising:
a first source/drain region;
a second source/drain region above the first source/drain region;
a gate electrode that extends between the first source/drain region and the second source/drain region; and
a channel layer that extends between the first source/drain region and the second source/drain region,
wherein the channel layer is included on at least two sides of the gate electrode and under a bottom surface of the gate electrode.

2. The semiconductor device of claim 1, wherein a first segment of the channel layer is between the gate electrode and the first source/drain region; and
wherein a second segment of the channel layer is between the gate electrode and the second source/drain region.

3. The semiconductor device of claim 2, wherein the first segment of the channel layer is on a first side of the gate electrode; and
wherein a third segment of the channel layer is on a second side of the gate electrode opposing the first side.

4. The semiconductor device of claim 1, wherein the channel layer comprises a U-shaped channel layer.

5. The semiconductor device of claim 1, further comprising:
a gate dielectric layer that extends between the first source/drain region and the second source/drain region,
wherein the gate dielectric layer is included on the at least two sidewalls of the gate electrode and under the bottom surface of the gate electrode.

6. The semiconductor device of claim 1, further comprising:
a source/drain interconnect structure above the storage structure and below the first source/drain region,
wherein the first source/drain region is coupled with the storage structure through the source/drain interconnect structure.

7. The semiconductor device of claim 1, wherein the first source/drain region is in direct physical contact with the storage structure.

8. The semiconductor device of claim 1, wherein the channel layer comprises a metal-oxide semiconductor material; and
wherein the semiconductor device further comprises:
one or more diffusion barrier layers between the first source/drain region and the second source/drain region.

9. A semiconductor device, comprising:
a plurality of backend dielectric layers; and
a memory cell structure, in the plurality of backend dielectric layers, comprising:
a storage structure;
a first source/drain region above the storage structure;
a second source/drain region above the first source/drain region;
a gate electrode having an elongated shape in a direction that is approximately perpendicular with the plurality of backend dielectric layers;
and
a channel layer that included on at least two sides of the gate electrode and under the bottom surface of the gate electrode,
wherein the first source/drain region is in contact with a bottom segment of the channel layer that is between a bottom surface of the gate electrode and the first source/drain region, and
wherein the second source/drain region is in contact with a side segment of the channel layer that is between a sidewall of the gate electrode and the second source/drain region.

10. The semiconductor device of claim 9, wherein a first segment of the channel layer is between the bottom surface of the gate electrode and the first source/drain region;
wherein a second segment of the channel layer is between a first side of the gate electrode and the second source/drain region; and
wherein a third segment of the channel layer is between a second side of the gate electrode and a third source/drain region.

11. The semiconductor device of claim 10, wherein the first side and the second side are opposing sides of the gate electrode.

12. The semiconductor device of claim 9, wherein the channel layer comprises a metal-oxide semiconductor material; and
wherein the semiconductor device further comprises:
a first diffusion barrier layer above the first source/drain region; and
a second diffusion barrier layer under the second source/drain region.

13. The semiconductor device of claim 12, wherein the first diffusion barrier layer and the second diffusion barrier layer each includes an oxide-containing material.

14. The semiconductor device of claim 12, wherein the first diffusion barrier layer and the second diffusion barrier layer each includes at least one of:
aluminum oxide (AlₓO_{y}),
silicon oxycarbide (SiOC), or
chromium oxide (CrₓO_{y}).

15. The semiconductor device of claim 9, further comprising:
a gate dielectric layer, comprising:
a first portion between the gate electrode and the first source/drain region, and between the gate electrode and the second source/drain region; and
a second portion above top surface of the second source/drain region.

16. The semiconductor device of claim 15, wherein the second portion of the gate dielectric layer is directly on the top surface of the second source/drain region.

17. A method, comprising:
forming, in a semiconductor device, a first source/drain region of a memory cell structure;
forming a plurality of dielectric layers over the first source/drain region;
forming, in the plurality of dielectric layers, a first source/drain interconnect and a second source/drain interconnect;
forming a conductive layer over the plurality of dielectric layers and on the first source/drain interconnect and the second source/drain interconnect;
forming, in the plurality of dielectric layers and through the conductive layer, a recess between the first source/drain interconnect and the second source/drain interconnect,
wherein forming the recess through the conductive layer results in formation of a second source/drain region above the first source/drain interconnect;
forming a channel layer on sidewalls and a bottom surface of the recess;
forming a gate dielectric layer on the channel layer in the recess; and
forming a gate electrode on the gate dielectric layer.

18. The method of claim 17, wherein forming the gate dielectric layer comprises:
forming a first portion of the gate dielectric layer on the channel layer in the recess; and
forming a second portion of the gate dielectric layer on a top surface of a dielectric layer of the plurality of dielectric layers; and
wherein the method further comprises:
filling the recess with a sacrificial layer on the gate dielectric layer prior to forming the gate electrode;
removing the second portion of the gate dielectric layer after filling the recess with the sacrificial layer; and
replacing the sacrificial layer with the gate electrode after removing the second portion of the gate dielectric layer.

19. The method of claim 18, wherein replacing the sacrificial layer with the gate electrode comprises:
removing the sacrificial layer from the recess after removing the second portion of the gate dielectric layer;
depositing additional material of the first portion of the gate dielectric layer in the recess,
wherein depositing the additional material of the first portion of the gate dielectric layer results in formation of a third portion of the gate dielectric layer on the dielectric layer; and
forming the gate electrode on the first portion of the gate dielectric layer in the recess after depositing the additional material of the first portion of the gate dielectric layer.

20. The method of claim 19, further comprising:
forming a word line conductive structure on the gate electrode and on the third portion of the gate dielectric layer,
wherein forming the word line conductive structure comprises:
depositing a conductive layer on the third portion of the gate dielectric layer and on the gate electrode; and
removing portions of the conductive layer,
wherein remaining portions of the conductive layer correspond to the word line conductive structure.
